(19) United States
(12) Patent Application Publication
(10) Pub. No.: US 2026/0140166 A1
(43) Pub. Date: May 21, 2026

(54) INTEGRATED CIRCUIT COMPONENT DIAGNOSIS USING REAL-TIME SENSOR-BASED VIOLATION INFORMATION

(71) Applicant: Intel Corporation, Santa Clara, CA (US)

(72) Inventors: Rakesh Kandula, Bangalore (IN); Rajesh Uppuluri, Bangalore (IN); Dror Zilberman, Kiryat Ono (IL)

(73) Assignee: Intel Corporation, Santa Clara, CA (US)

(21) Appl. No.: 18/949,702

(22) Filed: Nov. 15, 2024

(51) Int. Cl. G01R 31/28

(52) U.S. Cl. CPC G01R 31/287; G01R 31/2882

(57) ABSTRACT

Information pertaining to real-time sensor-based violations occurring during field operation of a failing integrated circuit component is used in conjunction with transition delay automatic test pattern generation (ATPG) test result information to diagnose the failing integrated circuit component. Real-time sensor-based violations can be captured during field operation at the integrated circuit component, with a sensor-based violation indicating that a sensor value generated by a sensor of the integrated circuit (such as a path margin monitor, temperature monitor, or voltage droop monitor) exceeds a sensor threshold value. Diagnosis of a failing integrated circuit component using real-time sensor-based violation information and transition delay ATPG test result information can aid in identifying a culprit path in the integrated circuit component that is likely responsible for causing the integrated circuit component failure.

### BACKGROUND

Automatic test pattern generation (ATPG) testing involves the automatic generation of test patterns meant to detect manufacturing or other faults in integrated circuit components and then performing fault detection tests using these test patterns. ATPG testing can detect stuck-at faults, transition delay faults, bridging faults, open circuit faults, and other types of faults. ATPG testing may not be able to test all paths in an integrated circuit component due to limitations in ATPG testing, which include the inability to exhaustively test the multitude of paths in modern integrated circuit components (modern systems-on-a-chip (SoCs) can comprise billions of transistors) practically.

### BRIEF DESCRIPTION OF THE DRAWINGS

FIG. 1 illustrates an example flow to diagnose integrated circuit component failures based on transition delay ATPG test result information and real-time sensor-based violation information.

FIG. 2 illustrates an interface for allowing sensor data generated by on-chip sensors compliant with the Test Access Port (TAP) protocol to be accessed via commands sent over an interconnect bus or fabric.

FIG. 3 illustrates sensors that are directly accessible from an interconnect bus or fabric.

FIG. 4 is a block diagram of a sensor monitoring architecture of an integrated circuit component.

FIG. 5 illustrates a logic block comprising three possible detection paths for a delay fault.

FIG. 6 illustrates the addition of path margin monitors to the logic block of FIG. 5.

FIG. 7 is a block diagram of an example computing device for identifying a culprit path in a failing integrated circuit component.

FIG. 8 is an example method of storing real-time sensor-based violations at an integrated circuit component during field operation of the integrated circuit component.

FIG. 9 is an example method of diagnosing a failing integrated circuit component to determine a culprit path in the integrated circuit component.

FIG. 10 is a block diagram of an example computing system in which technologies described herein (recording of real-time sensor-based violations of an integrated circuit component and diagnosis of a failing integrated circuit component) may be implemented.

FIG. 11 is a block diagram of an example processor unit to execute computer-executable instructions as part of implementing technologies described herein.

### DETAILED DESCRIPTION

Integrated circuit component manufacturers need to be adept at diagnosing integrated circuit component failures. These failing integrated circuit components can be components that are returned to them by original design manufacturers (ODMs), original equipment manufacturers (OEMs), or end-users, or components that failed during internal process development efforts or high-volume manufacturing. Typically, scan-based tests are used during failure analysis to aid in determining the root cause of integrated circuit component failures. The scan-based tests that have been predominantly used in diagnosing integrated circuit component faults include stuck-at tests (e.g., stuck-at-0, stuck-at-1), delay tests, memory tests, and cell-aware tests. Component failures due to stuck-at faults can be root-caused using stuck-at testing approaches that are well established. However, component failures due to delay defects are becoming a major concern in the semiconductor industry, especially when it comes to integrated circuit component testing and screening in high-volume manufacturing contexts.

Delay testing (or at-speed testing) uses transition delay (TD) patterns created by automatic test pattern generation (ATPG) tools to target delay-related faults due to manufacturing defects in integrated circuit components. Delay-related faults include path delays, the delay it takes for a signal to propagate along a circuit logic path, and transition delays, the delay it takes for a signal to transition from one state to another (typically the delay it takes for a digital signal to transition from a logical zero to a logical one value, and vice versa). Although transition delay ATPG testing can improve defect coverage beyond what stuck-at ATPG test patterns alone can achieve, transition delay testing is limited in its ability to reach test quality levels needed for nanometer-scale designs. As a result, a delay test approach known as small delay defect (SDD) ATPG testing is being utilized to achieve greater defect coverage than transition delay ATPG approaches.

The term “delay defect” refers to any type of physical defect, or an interaction of defects, that adds enough signal propagation delay in a component to produce an invalid response to applied inputs (or other errors) when the component runs at operational frequencies. Experimental data has shown that the distribution of delay-related failures in modern integrated circuit components is skewed towards smaller delays. That is, most components that fail due to delay defects fail because of small delay defects, delay defects that contribute to delays that are shorter (and in some cases, much shorter) than clock cycle times associated with leading-edge processors. Targeting these small delay defects during testing can improve defect coverage and lower test escape rates.

However, deploying SDD ATPG testing with full or a high degree of coverage in modern complex systems-on-chip (SoCs) would result in considerable increases in the cost of these products due to the very large number of paths that these SoCs can have. Thus, while TD ATPG testing has testing limitations related to test quality of coverage, SDD ATPG testing has limitations pertaining to test volume and test time.

These testing limitations can result in integrated circuit component manufacturers and ODMs spending enormous resources on integrated circuit component failure diagnosis. These resource expenditures can be driven by market necessities. For example, in the automotive context, failing integrated circuit components need to be debugged at an accelerated pace given potential human safety issues. The limitations of TD ATPG testing may mean that it could take an integrated circuit component manufacturer weeks before determining the root cause of an automotive integrated circuit component failure, or that the root cause may never be found. This may result in the manufacturer launching a product response team or even issuing a product recall.

Another class of limitations that ATPG testing is susceptible to is that components subjected to ATPG testing can experience conditions that differ from those experienced by the component functional testing or normal operation. For example, integrated circuit components can experience greater amounts of supply voltage droop or temperature fluctuations under ATPG testing due to signals toggling during the scan capture phase of ATPG scan-based testing at a rate that can exceed the toggling rate of signals during functional testing or normal operation. Thus, the various disadvantages of ATPG testing alone to diagnose an integrated circuit component can lead to a manufacturer being able to only approximate the root cause of a failing component, and not hone in on the exact root cause of the failure.

Reference is now made to the drawings, wherein similar or the same numbers may be used to designate the same or similar parts in different figures. The use of similar or same numbers in different figures does not mean all figures including similar or same numbers constitute a single or same embodiment. Like numerals having different letter suffixes may represent different instances of similar components. The drawings illustrate generally, by way of example, but not by way of limitation, various embodiments discussed in the present document.

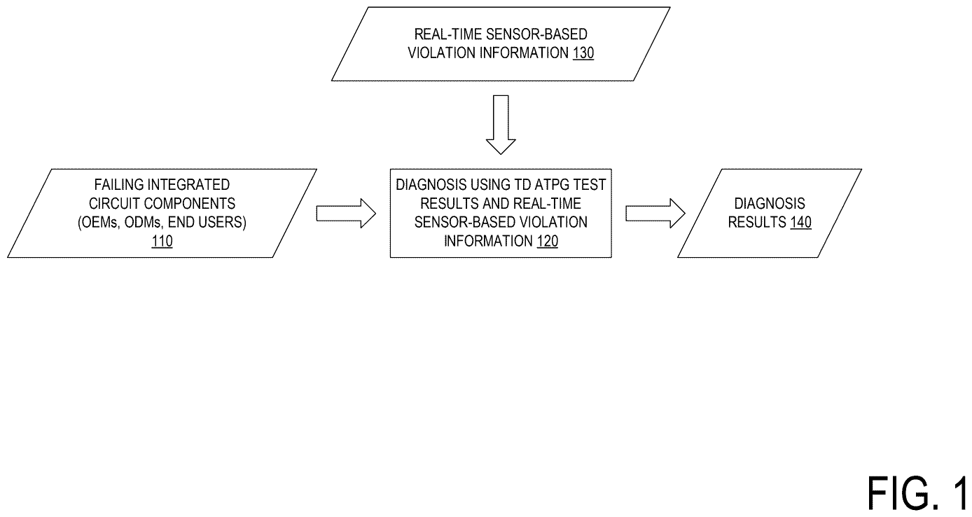

Disclosed herein are technologies that diagnose integrated circuit component failures based on transition delay ATPG test result information in conjunction with real-time sensor-based violation information generated during field operation of the failing integrated circuit components. FIG. 1 illustrates an example flow for diagnosing integrated circuit component failures based on ATPG test result information and real-time sensor-based violation information. Failing integrated circuit components 110 are returned from, for example, original equipment manufacturers (OEMs), original design manufacturers (ODMs), and end users. These components are diagnosed at 120 to determine the root cause of the failures. The diagnosis comprises using transition delay ATPG test result information and real-time sensor-based violation information 130 generated during field operation of the integrated circuit component. The sensor-based violation information 130 can be based on sensor data generated by path margin monitors, supply voltage droop monitors, temperature monitors, and other types of sensors located on integrated circuit components. Diagnosis 120 generates diagnosis results 140, which can indicate a culprit path (or multiple culprit paths) in the integrated circuit component that is causing (or most likely to be causing) the integrated circuit component to fail.

On-chip sensors, such as telemetry circuits, are used in existing integrated circuit component designs to monitor their performance after they are manufactured and can be used to determine the timing margin, or slack, in a path. Such circuits, such as path margin monitors, which are discussed in greater detail below, can measure the delay of a path using derived patterns, functional patterns, or naturally occurring signal activity. The data provided by these telemetry circuits, and analytics derived from such data, can help identify paths that have just enough timing margin and can be sensitive to small defects and PVT (process, voltage, temperature) variations that may cause signal delays. That is, the small delay caused by small defects and PVT variations may cause a fault. These small delays are typically not preventable, and telemetry circuits can provide for their monitoring.

Small signal delays can also be caused by complex interactions between processor cores with defects or activity in a neighboring core that creates a localized thermal and power distribution environment. In paths with little timing margin, these small signal delays can consume the limited timing margin and cause a fault. Such faults can be referred to as silent data errors, which may be intermittent and/or escape detection and can be difficult to track down. Silent data errors can be a particular concern for automotive chips, which can have very high quality standards for safety reasons. Automotive integrated circuit components may also be more susceptible to silent data errors as they need to operate over a greater temperature range (−40° C. to 125° C.) than the commercial temperature range (0° C. to 70° C.) used for consumer electronics (e.g., smartphones, laptops).

Telemetry circuits can also be used to measure local clock skew. Clock skew during normal operation of an integrated circuit component is usually tightly controlled but can be an issue during ATPG testing due to excessive switching activity and scan chains connecting flip-flops being driven by different branches of a clock tree. Telemetry circuits can further be used to monitor the amount of droop in the local power supply voltage due to IR drop in the power supply lines due to highly localized switching activity. Reduction in the power supply voltage supplied to logic gates increases their delay and the impact of power supply voltage droop on path delay can increase as the nominal power supply voltage continues to scale downwards in successive process technology nodes.

Telemetry circuits can further be used to measure on-chip noise. On-chip noise measurements can be used for various purposes, such as early silicon test and debug, speed characterization and timing margining, and power supply voltage droop and temperature measurements. On-chip noise measurements are useful in identifying and debugging noise issues in early silicon design, which can help reduce the time to market for new products. On-chip noise measurements can also be used to characterize the speed and timing performance of integrated circuit components in the presence of noise. This information can be used to optimize designs for speed and reliability. On-chip noise measurement can further be used to measure power supply voltage droop and temperature variations across an integrated circuit component. This information can be used to optimize the power distribution network of an integrated circuit component, and the thermal management solution used to cool the integrated circuit component. On-chip noise measurements can moreover be used to study the impact of noise on integrated circuit component wear-out (or aging) mechanisms. This information can be used to develop more reliable designs and to create predictive maintenance models.

The use of real-time sensor-based violation information generated during field operation of integrated circuit components in failure analysis can be advantageous for at least the reason that inclusion of this information in failure analysis can allow for a more accurate identification of the culprit path responsible for causing (or most likely causing) integrated circuit component failures. Whereas transition delay ATPG testing alone may only identify a set of suspect paths that may be responsible for an integrated circuit component failure, including real-time sensor-based violation information in the analysis may allow the individual path most likely to be causing the failure to be identified.

In the following description, specific details are set forth, but embodiments of the technologies described herein may be practiced without these specific details. Well-known circuits, structures, and techniques have not been shown in detail to avoid obscuring an understanding of this description. Phrases such as “an embodiment,” “various embodiments,” “some embodiments,” and the like may include features, structures, or characteristics, but not every embodiment necessarily includes the particular features, structures, or characteristics.

Some embodiments may have some, all, or none of the features described for other embodiments. “First,” “second,” “third,” and the like describe a common object and indicate different instances of like objects being referred to. Such adjectives do not imply objects so described must be in a given sequence, either temporally or spatially, in ranking, or in any other manner. Furthermore, the terms “comprising,” “including,” “having,” and the like, as used with respect to embodiments of the present disclosure, are synonymous.

As used herein, the term “integrated circuit component” refers to a packaged or unpacked integrated circuit product. A packaged integrated circuit component comprises one or more integrated circuit dies mounted on a package substrate with the integrated circuit dies and package substrate encapsulated in a casing material, such as a metal, plastic, glass, or ceramic. In one example, a packaged integrated circuit component contains one or more processor units mounted on a substrate with an exterior surface of the substrate comprising a solder ball grid array (BGA). In one example of an unpackaged integrated circuit component, a single monolithic integrated circuit die comprises solder bumps attached to contacts on the die. The solder bumps allow the die to be directly attached to a printed circuit board. An integrated circuit component can comprise one or more of any computing system component described or referenced herein or any other computing system component, such as a processor unit (e.g., system-on-a-chip (SoC), processor core, graphics processor unit (GPU), accelerator, chipset processor), I/O controller, memory, or network interface controller.

As used herein, the terms “operating”, “executing”, or “running” as they pertain to software or firmware in relation to a system, device, platform, or resource are used interchangeably and can refer to software or firmware stored in one or more computer-readable storage media accessible by the system, device, platform or resource, even though the software or firmware instructions are not actively being executed by the system, device, platform, or resource.

As used herein, the terms “sensor” and “monitor” can be used interchangeably. Thus, the terms “sensor-based violation” and “monitor-based violation” can refer to data generated by a sensor or monitor that exceeds a sensor or monitor threshold value.

In the following description, for purposes of explanation, numerous specific details are set forth in order to provide a thorough understanding thereof. It may be evident, however, that the novel embodiments can be practiced without these specific details. In other instances, well-known structures and devices are shown in block diagram form in order to facilitate a description thereof. The intention is to cover all modifications, equivalents, and alternatives within the scope of the claims.

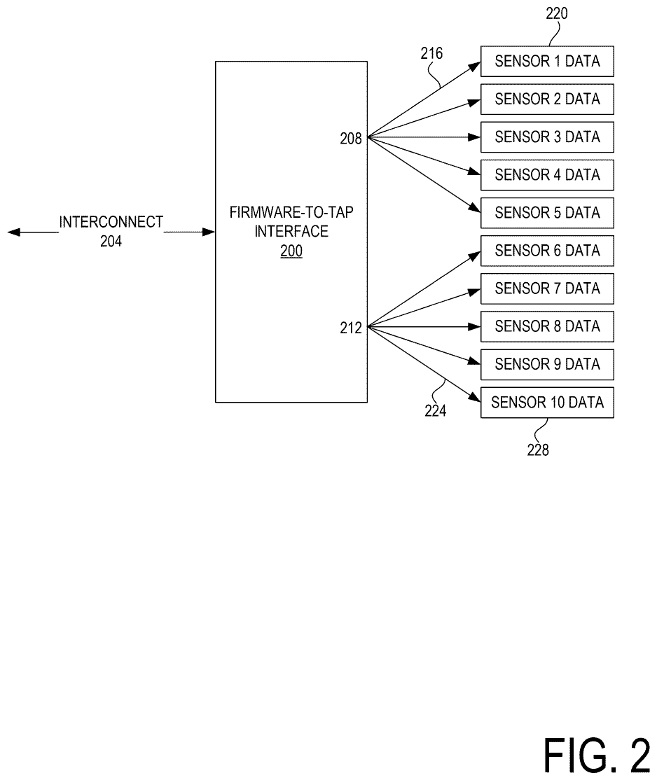

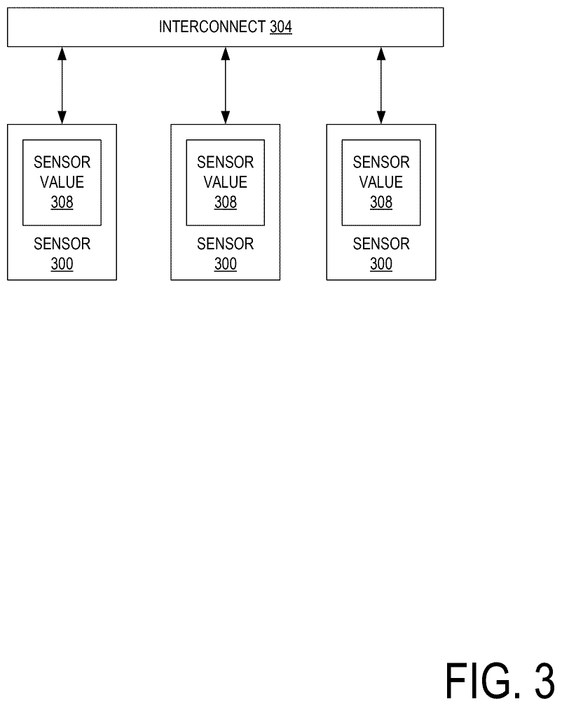

To be able to use real-time sensor-based violation information during diagnosis of a failing integrated circuit component, the real-time sensor-based violation information is first collected and stored during field operation of the integrated circuit component. FIGS. 2 and 3 illustrate two ways of collecting and storing real-time sensor-based violation information at an integrated circuit component. FIG. 2 illustrates an interface allowing sensor data generated by on-chip sensors compliant with the Test Access Port (TAP) protocol to be accessed via commands sent over an interconnect bus or fabric. The interface 200 can convert commands sent over the interconnect 204 to one or more commands that are compliant with the TAP protocol. The interconnect 204 can be an interconnect bus or interconnect fabric, such as an APB (Advanced Peripheral Bus) bus, AXI (Advanced Extensible Interface) bus, AHB (Advanced High-performance Bus), IOSF (Intel On-chip System Fabric) sideband fabric, NoC (Network-on-Chip) bus, or other suitable bus or fabric. The commands sent over the interconnect 204 to the interface 200 can be firmware commands or other suitable commands.

The interface 200 comprises two banks of TAP interfaces from which sensor data stored in remote test data registers can be read. The first bank 208 of TAP interfaces provides access to remote test data registers 1-5 and the second bank 212 of TAP interfaces provides access to remote test data registers 6-10. For example, interface bank 208 comprises interface 216 from which sensor data 220 generated by a sensor identified as “sensor 1” can be retrieved, and interface bank 212 comprises interface 224 from which sensor data 228 generated by a sensor identified as “sensor 10” can be retrieved.

FIG. 3 illustrates sensors 300 that are directly accessible from an interconnect bus or fabric 304. The sensors 300 can be direct MMIO (memory-mapped I/O) accessible registers. Thus, a sensor value 308 generated by a sensor 300 can be read by a memory read instruction sent over the interconnect 304 that reads the contents of a memory address mapped to one of the sensors 300.

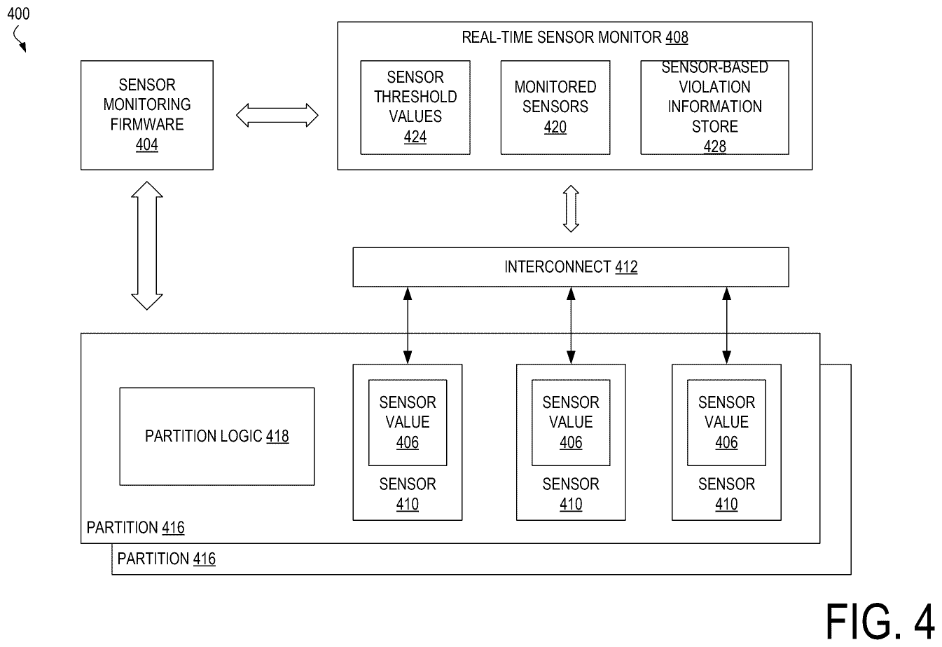

FIG. 4 is a block diagram of a sensor monitoring architecture of an integrated circuit component. The architecture 400 comprises sensor monitoring firmware 404, a real-time sensor monitor 408, an interconnect 412, and partitions 416 of an integrated circuit component. The individual partitions 416, which can be functional or physical partitions, comprise partition logic 418 and sensors 410. The individual sensors 410 generate a sensor value 406. The partition logic 418 can be any logic located in an integrated circuit component partition, such as a processor core, memory, or I/O controller (e.g., PCIe (Peripheral Component Interconnect express) controller or USB (Universal Serial Bus) controller).

The real-time sensor monitor 408 stores information indicating which sensors 410 are to be monitored during field operation of the integrated circuit component (monitored sensors 420), sensor threshold values for those sensors (sensor threshold values 424), and sensor-based violations information in a sensor-based violation information store 428. The sensor threshold values 424 and monitored sensors 420 can be set according to messages received by the real-time sensor monitor 408 from the sensor monitoring firmware 404. The sensor threshold values 424 can comprise, for the individual monitored sensors 420, one sensor threshold value or multiple sensor threshold values, with the multiple sensor threshold values indicating various severity or criticality levels.

For example, a temperature sensor threshold value can be a single threshold value T1, with temperature sensor values below T1 indicating a “safe” temperature sensor value and sensor values exceeding T1 indicating a temperature sensor-based violation and an “abnormal” or “not safe” temperature sensor value (and the presence of). In another example, a temperature sensor threshold value comprises two sensor threshold values—T1 and T2—that indicate different sensor-based violation severities or criticalities. For example, temperature sensor values below T1 can indicate a safe temperature sensor value, temperature sensor values greater than T1 but less than T2 can indicate a “borderline” temperature sensor value, and temperature sensor values greater than T2 can indicate an “abnormal” or “not safe” temperature sensor value.

In general, sensor values not exceeding a corresponding sensor threshold value can indicate that the sensor value is a “safe” value, and sensor values exceeding a sensor threshold value can indicate that the sensor value is an “abnormal” sensor value and that a sensor-based violation has occurred. The sensor threshold values can be absolute values (e.g., 1.05 V, 120° C.), a percentage of another value (e.g., 90% of VDD, 105% of Tj max), or other suitable values. As used herein, the word “exceeding” in the context of a sensor value exceeding a sensor threshold value can, for the appropriate sensor type, refer to a sensor value that is less than a sensor threshold value. For example, for voltage droop monitors, the sensor threshold value can be a value that is less than a typical power supply voltage, and a voltage drop monitor sensor value exceeding a voltage droop monitor threshold value can be a voltage drop monitor sensor value that is less than the voltage droop monitor sensor threshold value, indicating that a localized power supply voltage value has dropped to an “abnormal” value.

The real-time sensor monitor 408 can monitor the sensor values 406 during field operation of the integrated circuit component. As used herein, the term “field operation” refers to operation of an integrated circuit component after it has been sold by an integrated circuit component manufacturer. Thus, field operation of an integrated circuit component includes operation of an integrated circuit component by an end user, ODM, OEM, or any other party that has purchased the integrated circuit component from an integrated circuit component manufacturer.

The sensor monitor 408 can monitor the sensor values 406 in various manners. In some embodiments, a sensor threshold value 424 for a sensor 410 is stored at the sensor 410 and the sensor 410 sends an interrupt or other message to the sensor monitor 408 indicating that a sensor-biased violation has occurred—that the sensor value 406 for the sensor 410 exceeds the sensor threshold value 424. In response to receiving the interrupt or other message, the sensor monitor 408 can update the sensor-based violation information store 428 to capture the sensor-based violation. In the embodiment illustrated in FIG. 4, the sensor values 406 are direct MMIO accessible registers. In other embodiments, the sensors 410 are TAP-compliant sensors and sensor values 406 can be read by the sensor monitor 408 sending the appropriate commands to a firmware-to-test access point interface.

In other embodiments, the sensor monitor 408 can read the sensor values 406 when a partition 416 is in a low-power state. As used herein, the term “low-power state” when referencing a state of a partition refers to a state in which the partition is operating at a lower power consumption level than when the partition is operating in an active state. A partition can operate in one or more low-power states with one difference between the low-power states being characterized by the power consumption level of the partition. Such low-power states can be characterized as “standby”, “idle”, “sleep” or “hibernation” states. As used herein, the term “active state” when referencing a partition state refers to a state in which the partition is fully usable. That is, the full capabilities of the partition are available. A partition can be temporarily placed in a high-performance mode while the partition is in an active state to accommodate demanding workloads. Thus, a partition can operate within a range of power levels while in an active state. In some embodiments, whether a partition in an integrated circuit component is in a low-power state can be determined by a power management controller or central controller located in the integrated circuit controller or a platform-level power management controller or central controller that controls multiple integrated circuit components in a computing system.

In still other embodiments, the sensor monitor 408 can monitor the sensor values 406 at periodic intervals to see if the sensor values 406 exceed their corresponding sensor threshold values 424. Although a single sensor monitor 408 is illustrated in FIG. 4, separate sensor monitors 408 can be dedicated to individual partitions 416.

The sensor-based violation information store 428 can be part of the real-time sensor monitor 408 or external to the real-time sensor monitor 408. For example, the sensor-based violation information store 428 can be any (or part of any) memory, such as registers or an SRAM (static random-access memory) that is part of the partition 416 or part of the integrated circuit component that partition 416 is a part of, or a memory or storage device that is external to the integrated circuit component, such as DRAM (dynamic random-access memory), flash memory or any other memory or storage device described or referenced herein that can be part of a computing system's memory hierarchy. In some embodiments, the sensor-based violation information store 428 is stored external to a computing device comprising the integrated circuit component, such as at a remote computing device or storage device accessible via one or more networks from the computing device comprising the integrated circuit component.

The sensor-based violation information store 428 can store various types of information indicating sensor-based violations. For example, the store 428 can comprise, for the individual sensors 410, a counter indicating the number (or a count) of sensor-based violations that have occurred during field operation. The store 428 can store multiple counters for individual sensors 410 if the sensor threshold values 424 for a sensor indicate multiple levels of severity or criticality (e.g., borderline, abnormal), with the individual counters indicating the number of times the sensor value 406 for a sensor 410 exceeds a sensor threshold value. That is, in these embodiments, the store can comprise, for example, a counter indicating the number of times “borderline” violations for a sensor have occurred and a counter indicating the number of times “not safe” or “abnormal” violations have occurred. In some embodiments, the counter for a sensor can indicate the number of times a real-time sensor monitor 408 received a message (such as an interrupt) from a sensor 410 indicating a sensor-based violation.

The real-time sensor monitor 408 can update sensor-based violation information stored in the sensor-based violation information store 428 in response to receiving an interrupt or message from a sensor indicating a sensor-based violation or the sensor monitor 408 reading a sensor value 406 and determining that the sensor value 406 exceeds a corresponding sensor threshold value 424. In some embodiments, this updating can comprise increasing a counter indicating the number of sensor-base violations for the appropriate sensor.

In some embodiments, the sensor-based violation information store 428 can store information indicating which partition in an integrated circuit component a sensor is located in, for the sensor associated with sensor-based violation information stored in the store 428. This partition-identifying information can take any suitable form, such as a sensor identifier that identifies a sensor from among other sensors across partitions in an integrated circuit component (e.g., “core 1_VDM 1”), or a sensor identifier that identifies a sensor within a partition (e.g., “VDM 1”) along with information identifying the partition in the integrated circuit component (e.g., “core 1”). A sensor identifier can be used to determine which paths in an integrated circuit component sensor-based violation information is to be associated with. For example, an integrated circuit component manufacturer can use a sensor identifier to determine which paths are to be associated with sensor-based violation information based on information available to the integrated circuit component manufacturer regarding the integrated circuit component design. Such information can take various suitable forms, such as an integrated circuit component design database storing information indicating sensor-to-path associations.

The sensors 410 can comprise various sensor types, such as voltage droop monitors, path margin monitors, temperature sensors, process variation sensors, noise sensors, clock skew monitors, aging sensors, or other suitable sensors. A path margin monitor can monitor the delay of a path in a partition, such as the delay of a path between sequential logic elements (such as flip-flops) or if the delay of a path exceeds a path margin threshold value. Path margin monitors are discussed in greater detail below.

A voltage droop monitor can monitor a local power supply voltage value or if a local power supply voltage value has dropped below a power supply voltage threshold value. A temperature sensor can indicate the temperature at a location in a partition or indicate that the temperature at the location in the partition has exceeded a temperature threshold value. In some embodiments, temperature sensors can act as process variation sensors. Example temperature sensors include diode-based temperature sensors, bandgap temperature sensors, digital thermal sensors, and resistance temperature detectors. A process variation sensor can indicate the process variation at a location in a partition or indicate that the process variation at the location in the partition exceeds a process variation threshold value. These process variations include, for example, differences in transistor dimensions, doping concentration, and material properties. Example process variation sensors include delay chains, ring oscillators, transistor threshold voltage (Vth) monitors, and leakage current monitors.

A noise sensor can indicate the noise at a location in a partition or indicate that the noise at the location in the partition has exceeded a noise threshold value. In some embodiments, noise sensors can measure power supply voltage droop. Example noise sensors include power supply noise sensors (which can measure power supply voltage droop), substrate noise sensors, and noise sensors that measure crosstalk between neighboring lines or traces. An aging sensor can indicate the aging at a location in a partition due to, for example, the effects of temperature, voltage stress, or operational load on transistors over time (due to, for example, hot carrier injection or negative bias temperature instability), and can indicate that transistor aging at the location in the partition has exceeded an aging threshold value. Example aging sensors include ring oscillator-based sensors, delay line sensors, HCI (hot carrier injection) sensors, threshold voltage (Vth) sensors, and electromigration sensors. A clock skew monitor sensor can indicate the clock skew at a location in a partition or indicate that the clock skew at the location in the partition has exceeded a clock skew threshold value. Example clock skew monitors include delay chain-based monitors, time-to-digital converters, phase-locked loop monitors, and pulse width monitors.

A partition in an integrated circuit component can comprise multiple sensor types and can have one or more sensors for the individual sensor types located in a partition. For example, a partition could have several (e.g., ones of, tens of) clock skew sensors and a substantial number (e.g., hundreds of, thousands of) path margin monitors.

In some embodiments, the real-time sensor monitor 408 can send a message to a sensor analytics engine (not illustrated in FIG. 4) that can generate additional sensor-based violation information based on one or more sensor-based violations. The sensor analytics engine can be a trained machine learning model, sensor analytics software or firmware, or other suitable software or firmware component. The additional sensor-based violation information generated by a sensor analytics engine can be based on information indicating multiple sensor-based violations, such as a present sensor-based violations and one or more prior sensor-based violations. In some embodiments, the multiple individual sensor-based violations comprise multiple sensor values associated with the multiple sensor-based violations. The sensor analytics engine can generate sensor-based violation information indicating, for example, that a particular path is likely to be at fault for an integrated circuit component failure, or predictive failure information, such as that the integrated circuit component is likely to exhibit an operational failure in the near future. The sensor-based violation information generated by the sensor analytics engine can be stored in the sensor-based violation information store. The sensor analytics engine can be part of a sensor-based monitor (e.g., 420), part of an integrated circuit component, or external to the integrated circuit component containing the sensors corresponding to the sensor-based violations for which the sensor analytics engine is generating sensor-based violation information.

The sensor-based violation information stored in the sensor-based violation information store 428 can be provided by an integrated circuit component in response to a request for such information. This information can be requested by, for example, an integrated circuit component manufacturer performing failure analysis on the integrated circuit component.

As previously mentioned, the sensor-based violation information captured during field operation of an integrated circuit component can be used in conjunction with transition delay ATPG test result information during the diagnosis of failing integrated circuit components to identify a culprit path that is most likely to be the root cause of the integrated circuit component failure. Performing failure analysis on a failing integrated circuit component using ATPG test result information alone may not allow for identification of a culprit path.

In the context of delay defects, using transition delay ATPG test result information alone to identify a culprit path has its shortcomings. The goals of transition delay ATPG testing can include minimizing test run time and test pattern count, not to cover small delay defects (SDDs). Transition delay ATPG testing targets delay defects by generating a first test pattern to launch a transition through a potential delay fault site, which may activate either a slow-to-rise or a slow-to-fall defect, and a second test pattern to capture the response. During transition delay ATPG testing, if a signal propagating along a path activated by a test pattern does not propagate to an endpoint (a primary output or scan flip-flop) within the at-speed cycle time, incorrect data is captured. The captured incorrect data indicates a delay defect in the activated path.

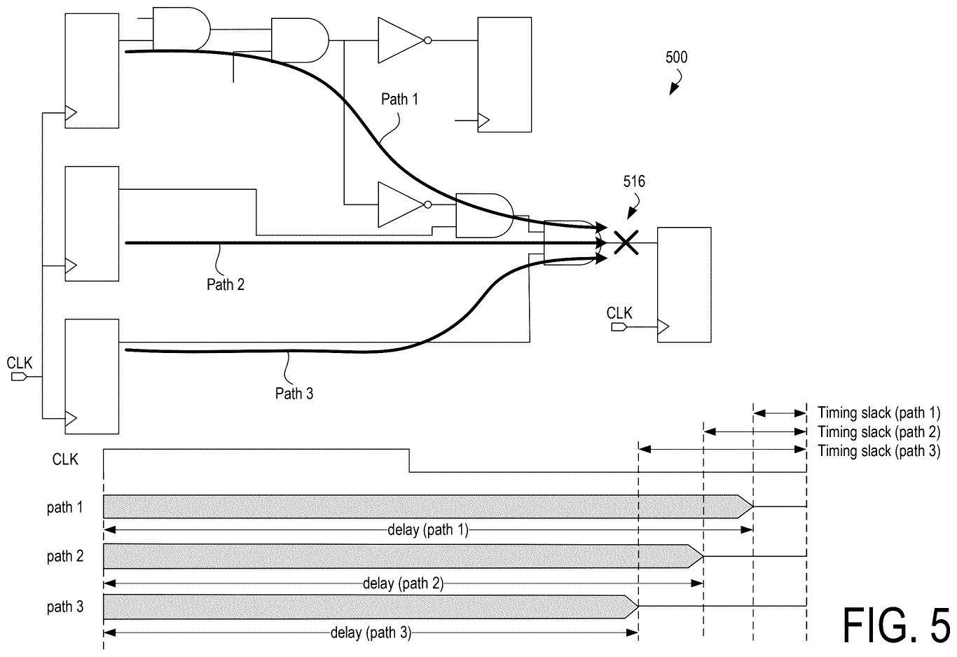

To minimize test run time and test pattern count, transition delay ATPG targets transition delay faults along the easiest sensitization and detection paths (e.g., paths with minimal conflict constraints, the simplest logic, or paths not having complex logic structures, such as those with feedback loops) it can find. Often, the easiest sensitization and detection paths are the shortest paths. To understand how this can impact small delay defect coverage, consider FIG. 5.

FIG. 5 illustrates a logic block comprising three possible detection paths for a delay fault. The logic block 500 comprises paths 1, 2, and 3 that can be used for detecting a fault 516. Transition delay ATPG testing typically generates pattern sequences that target the fault along the path that has the largest timing slack (that is, the path that has the largest tolerance for the amount of delay that could be injected into the path with causing a fault), which is path 3 in the case of logic block 500. Path 3 also has the lowest path delay. A transition delay ATPG test pattern sequence that covers path 3 would not cover small delay defects associated with paths 1 and 2. Owing to the smaller timing slack in paths 1 and 2, small delay defects in either of those two paths would be more likely to consume those paths' timing slacks and cause a delay fault.

Transition delay ATPG testing does manage to detect some small delay defects either directly as targeted faults or indirectly as bonus faults when targeting other faults, but it does not provide full small defect delay coverage in all paths. Even with the limited small delay defect coverage that can be provided by transition delay ATPG testing, transition delay ATPG testing may rarely detect small delay faults along longer paths needed to detect defects of the smallest “size” (that is, delay). This is because small delay defects causing small delays in the path having the largest timing slack (e.g., path 3) may not cause a fault due to that path's large timing slack.

Thus, transition delay ATPG testing is effective for detecting delay defects of relatively nominal to large delay, but because it does not explicitly target delay faults along the paths having the lowest slack, it is not effective in detecting delay defects causing relatively small delays. And, as already noted, deploying small defect delay testing at a large scale may not be practical due to its considerable cost in terms of testing time, due to both the generation of a large number of test patterns and the testing time to perform tests using the large set of test patterns.

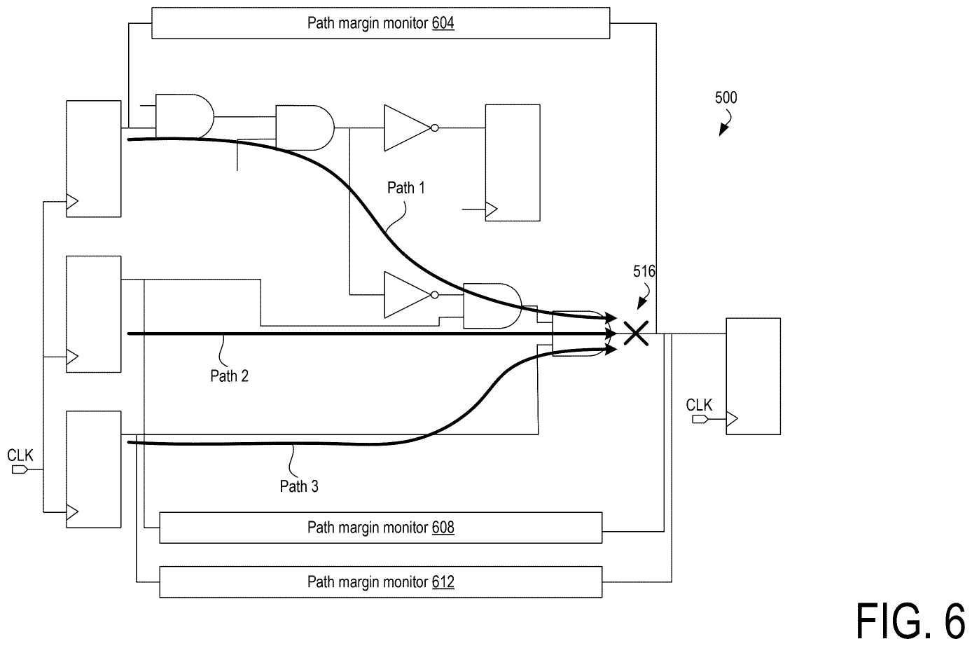

FIG. 6 illustrates the addition of path margin monitors to the logic block 500 of FIG. 5. Path margin monitors (PMMs) are circuits that can monitor the slack of a path. In some embodiments, a path margin monitor can provide a message or an interrupt indicating a sensor-based violation when the slack drops below a sensor threshold value. FIG. 6 illustrates the addition of path margin monitors 604, 608, and 612 that monitor the slack of paths 1, 2, and 3, respectively. The path margin monitors 604, 608, and 612 may have been added to monitor these paths because they are critical paths. If the sensor threshold value for the path margin monitors 604, 608, or 612 is, for example, five picoseconds, the path margin monitors can send a message or interrupt to a sensor monitor (e.g., sensor monitor 408) indicating that the slack of a path has dropped below the sensor threshold slack value of five picoseconds. The slack of a path may have reduced from an initial value (e.g., 20 picoseconds) for various reasons, such as aging of transistors in the path, excess power supply voltage droop due to intense activity in logic located near paths 1-3, excessive temperature experienced by the path (causing reduced carrier mobility), etc. The path margin monitors 604, 608, and 612 can provide information indicating a sensor-based violation, by providing information indicating, for example, the delay of the path, the slack in the path (the delay between a signal transition at the end of the path and a next clock edge (e.g., the delay between the fault 516 in a path that is being tested for a default and a next rising edge of the CLK signal in FIGS. 5 and 6), a change in the path delay or a change in the slack since the integrated circuit component was placed into service in the field, or other suitable information.

As previously discussed, monitors or sensors other than path margin monitors can be used in integrated circuit components, and information indicating sensor-based violations of these other sensor types can be generated and stored during field operation of the integrated circuit component. The location of sensors or monitors corresponding to sensor-biased violation information utilized during integrated circuit component failure analysis can be determined based on sensor-identifying information that may be provided with or contained in sensor-based violation information. In some embodiments, depending on the type of sensor, a sensor can correspond to a single path (such as the path margin monitor 604, 608, and 612), or multiple paths. In an example of the latter, sensor-based violation information for a temperature sensor can be used during failure analysis in analyzing multiple paths in the physical vicinity of the temperature sensor, as the temperature measured by a temperature sensor may provide a sufficient representation of the temperature experienced by a large number of paths in the vicinity of the temperature sensor. As stated above, information indicating sensor-to-path associated can be stored in an integrated circuit component design database, which can be accessible to the integrated circuit component manufacturer.

The following example illustrates the use of real-time sensor-based violation information generated by path margin monitors in conjunction with transition delay ATPG test result information to determine the root cause (or likely root cause) of a failing integrated circuit component. In this example, the failing integrated circuit component is a multi-core central processing unit returned to an integrated circuit component manufacturer by an ODM. The failing integrated circuit component comprises a logic block having paths 1 through 3 as illustrated in FIG. 5, as well as a fourth path, path 4 (not illustrated in FIG. 5 or 6) in the logic block that is parallel to paths 1-3 (that is, the output of path 4 is tied to the outputs of paths 1-3) and has a timing slack less than that of path 3. Paths 1-4 are in a core identified as “core 2”.

The diagnosis of the failing integrated circuit component laid out in this example, as well as any other integrated circuit component diagnosis approach described herein, can be performed by software, firmware, hardware, or a combination thereof on one or more computing systems.

ATPG stuck-at and memory BIST (built-in self-test) tests are performed as an initial step in the failure analysis process, and the integrated circuit component passes those tests. The integrated circuit component manufacturer then concludes that the integrated circuit component may be failing due to timing issues. Consulting real-time sensor-based violation information provided by the failing integrated circuit component, paths 1 and 3 of the logic block indicate the presence of sensor-based violations during field operation, and transition delay ATPG test patterns are generated for the logic block comprising paths 1-4. ATPG test pattern generation can have access to a timing database comprising information indicating slack information for paths in the integrated circuit component. As discussed previously, because transition delay ATPG test pattern generation may produce test patterns for paths having the greatest amount of slack, transition delay ATPG testing only tests path 3 out of paths 1-4 as path 3 has the greatest amount of slack. Knowing the limitations of transition delay ATPG testing, the integrated circuit component manufacturer correlates the transition delay ATPG testing results with the real-time sensor-based violation information corresponding to path margin monitors monitoring the path margin of paths 1 through 4 to try and determine the culprit path responsible for the integrated circuit component to fail.

In implementations where this diagnosis is performed by a computing system, the computing system can first receive transition delay ATPG test result information for one or more paths in the integrated circuit component. The computing system can then receive, for respective of the one or more paths, sensor-based violation information associated with the respective path. The sensor-based violation information indicates sensor-based violations that occurred during field operation of the integrated circuit component. The sensor-based-violations can be associated with a single sensor type (e.g., path margin monitors) associated with a path or multiple sensor types (e.g., path margin monitor, voltage droop monitor, and temperature sensors) associated with a path. Having received the transition delay ATPG test result information and the sensor-based violation information, the computing system can determine a failing path (or a culprit path) from among the one or more paths based on the transition delay ATPG test result information and the sensor-based violation information associated with one or more paths.

Table 1 shows ATPG test result information and sensor-based violation information for paths 1-4. Table 1 shows real-time sensor-based violation information associated with path margin monitors (PMMs 1 through PMMs 4) for each path, a criticality determined by sensor analytics software, and the number of messages generated by each path margin monitor indicating a path margin monitor-based violation (the slack of a path falling below the slack timing threshold value). In this example, the criticality of a path, as determined by the sensor analytics software is “safe” or “not safe”, which could be determined by, for example, the number of violation messages being greater than a specified value, such as five hundred, one thousand, etc. The transition delay ATPG test result information does not shed any light on which path may be the root cause of the integrated circuit component failure as transition delay ATPG testing only covers path 3, which passed transition delay ATPG testing. The number of sensor-based violations and the sensor-based criticality columns in Table 1 indicate that path 1 is more likely to be the culprit path than path 3. Path 1 had a much larger number of sensor-based violations during field operation than path 3 (greater than 10,000 vs. less than 100) and the criticality for path 1 was determined to be “not safe” while the criticality of path 3 was determined to be “safe”. As a result of this diagnosis, path 3 is identified as the culprit path.

TABLE 1
Transition Delay ATPG Test Result Information
and Real-Time Sensor-Based Violation Information
Based on Path Margin Monitors for Paths 1-4.

| | | | Number of | | |
|---|---|---|---|---|---|
| | | Sensor-based | sensor-based | | |
| | | criticality | violation | | |
| | Sensor | during | messages sent | | TD ATPG |
| | identi- | field | during field | Parti- | test |
| Path | fier | operation | operation | tion | results |
| 1 | PMM1 | Not Safe | >10,000 | Core 2 | Not covered |
| 2 | PMM2 | Safe | 0 | Core 2 | Not covered |
| 3 | PMM3 | Safe | <100 | Core 2 | Pass |
| 4 | PMM4 | Safe | 0 | Core 2 | Not covered |

With path 1 identified as a culprit path, the integrated circuit component manufacturer could take various actions to remedy the integrated circuit component design to make it less susceptible to the identified path 1 fault, such as redesigning the path logic, changing the physical layout of the path to make it less susceptible to process variations, increasing the robustness of the power distribution routing in the vicinity of the path, or other suitable action. Further, although the diagnosis approaches disclosed herein can help identify the most likely culprit path, they can also aid in identifying multiple possible culprit paths and help diagnosis efforts by helping diagnosis engineers prioritize which paths of the multiple culprit paths identified during diagnosis should be investigated further.

This example is just one possible example of how sensor-based violation information generated during real-time field operation of an integrated circuit component can be used to diagnose a failing integrated circuit component. In other examples, just the criticality of the sensor-based violations for the paths or the number of sensor-based violations detected during field operation could be used in addition to transition delay ATPG test result information to determine a culprit path.

Continuing with this diagnosis example, sensor-based violation information based on sensor data generated by sensor types other than path margin monitors in identifying a culprit path. Tables 2 and 3 show sensor-based violation information for digital temperature sensors (DTS1-DTS4) and voltage droop monitors (VDM1-VDM4) associated with paths 1-4. Each path has its own associated digital temperature sensor and voltage droop monitor. Tables 2 and 3 reinforce the conclusion that path 1 is the culprit path. Even though the sensor-based violations based on the digital temperature sensors indicate that both paths 1 and 3 are not safe and both have many sensor violations, path 1 has more sensor violations than path 3. And, there is no information in Table 3 contradicting the information in the Tables 1 and 2 that suggest that path 1 is the culprit. The information in Table 3 indicates that paths 1 and 3 are safe and both have less than 100 sensor-based violations.

TABLE 2
Transition Delay ATPG Test Result Information and
Real Time Sensor-Based Violation Information based
on Digital Temperature Sensors for Paths 1-4.

| | | Sensor-based | Number of sensor | | |
|---|---|---|---|---|---|
| | | criticality | violation | | |
| | Sensor | during | messages sent | | TD ATPG |
| | identi- | field | during field | Parti- | test |
| Path | fier | operation | operation | tion | results |
| 1 | DTS1 | Not Safe | >10,000 | Core 2 | Not covered |
| 2 | DTS2 | Safe | 0 | Core 2 | Not covered |
| 3 | DTS3 | Not Safe | >5,000 | Core 2 | Pass |
| 4 | DTS4 | Safe | 0 | Core 2 | Not covered |

TABLE 3
Transition Delay ATPG Test Result Information and
Real Time Sensor-Based Violation Information based
on Voltage Droop Monitors for Paths 1-4.

| | | Sensor-based | Number of sensor | | |
|---|---|---|---|---|---|
| | | criticality | violation | | |
| | Sensor | during | messages sent | | TD ATPG |
| | identi- | field | during field | Parti- | test |
| Path | fier | operation | operation | tion | results |
| 1 | VDM1 | Safe | <100 | Core 2 | Not covered |
| 2 | VDM1 | Safe | 0 | Core 2 | Not covered |
| 3 | VDM1 | Safe | <100 | Core 2 | Pass |
| 4 | VDM1 | Safe | 0 | Core 2 | Not covered |

As illustrated in this example, identification of a culprit path comprises identifying the path with a greatest sensor-based violation count (number of sensor-based violations) and not covered by ATPG testing that generated the transition delay ATPG test result information for the path. In other embodiments, identification of a culprit path comprises identifying the path with a greatest sensor-based violation count (number of sensor-based violations). In still other embodiments, identification of a culprit path comprises identifying a path having an associated criticality indicating that the path is not safe. In yet other embodiments, identification of a culprit path comprises identifying a path having an associated criticality indicating that the path is not safe and not covered by ATPG testing that generated the transition delay ATPG test result information for the path.

In some embodiments where the sensor-based violation information is associated with two sensor types, identification of a culprit path comprises identifying as the path associated with the greatest number of sensor-based violations associated with a first sensor type and the greatest number of sensor-based violations associated with a second sensor type. In other embodiments comprising two sensor types, identification of a culprit path comprises identifying as the path associated with a greatest number of sensor-based violations associated with the first sensor type and a greatest number of sensor-based violations associated with the second sensor type and not covered by ATPG testing that generated the transition delay ATPG test result information for the path. In yet other embodiments comprising two sensor types, identification of a culprit path comprises identifying the path having an associated criticality associated with the first sensor type indicating that the path is not safe and having an associated criticality of sensor-based violations associated with the second sensor type indicating that the path is not safe. In still other embodiments comprising two sensor types comprising two sensor types, identification of a culprit path comprises identifying the path having an associated criticality associated with the first sensor type indicating that the path is not safe and having an associated criticality of sensor-based violations associated with the second sensor type indicating that the path is not safe and not covered by ATPG testing that generated the transition delay ATPG test result information for the one or more paths.

In some embodiments where the sensor-based violation information is associated with three sensor types, identification of a culprit path comprises identifying as the path associated with a greatest number of sensor-based violations associated with a first sensor type, a greatest number of sensor-based violations associated with a second sensor type, and a greatest number of sensor-based violations associated with a third sensor type. In other embodiments comprising third sensor types, identification of a culprit path comprises identifying as the path associated with a greatest number of sensor-based violations associated with the first sensor type, a greatest number of sensor-based violations associated with the second sensor type, a greatest number of sensor-based violations associated with the second sensor type, and not covered by ATPG testing that generated the transition delay ATPG test result information for the path. In yet other embodiments comprising three sensor types, identification of a culprit path comprises identifying the path having an associated criticality associated with the first sensor type indicating that the path is not safe, having an associated criticality of sensor-based violations associated with the second sensor type indicating that the path is not safe, and having an associated criticality of sensor-based violations associated with the third sensor type indicating that the path is not safe. In still other embodiments comprising three sensor types comprising two sensor types, identification of a culprit path comprises identifying the path having an associated criticality associated with the first sensor type indicating that the path is not safe, having an associated criticality of sensor-based violations associated with the second sensor type indicating that the path is not safe, having an associated criticality of sensor-based violations associated with the third sensor type indicating that the path is not safe, and not covered by ATPG testing that generated the transition delay ATPG test result information for the one or more paths.

Tables 1-3 illustrate an example situation in which four paths in a logic block each are associated with their own path margin monitor, temperature sensor, and voltage droop monitor. In other embodiments or examples, fewer than three sensors may be deployed for individual paths (such as only a path margin monitor or only a voltage droop monitor for each path). Based on the relationships between delay, temperature, and power supply voltage, as touched upon above and discussed in greater detail below, diagnostic engineers could come to a conclusion on which path is a culprit path without having dedicated path margin monitors, temperature sensors, and voltage droop monitors for each path.

When the temperature of a digital logic gate increases, the delay of the gate typically increases as well. This is due to several temperature-dependent properties of semiconductor-based devices. For example, the mobility of charge carriers (electrons and holes) in the semiconductor material decreases with increasing temperature. This is because the lattice vibrations (phonons) within the silicon increase with temperature, leading to more frequent scattering of the charge carriers. Reduced mobility means that charge carriers move more slowly through the channels of transistors, which in turn slows down their switching speed.

When the power supply voltage of a digital logic gate increases, the delay of the gate typically decreases. This is because a higher power supply voltage increases charge carrier concentration in transistor channels and increases the electric field between the source and the drain of transistors (which increases charge carrier drift velocity). As a result, the transistors can switch states faster, leading to a reduction in both digital logic gate rise times (the time it takes for digital logic gate outputs to transition from a low voltage to a high voltage) and fall times (the time it takes for a digital logic gate output to transition from a high voltage to a low voltage).

Various power supply voltages can be used in an integrated circuit component. The core voltage of an integrated circuit component is the voltage supplied to the core logic of an integrated circuit component, which includes the logic of CPU, GPU, and other processor units. The core voltages in modern SoCs can be in the range from around 0.7 V to 1.2 V, with integrated circuit components fabricated at advanced technology nodes (e.g., 7 nm or later) operating at the lower end of this range or even lower to save power and reduce heat. The power supply voltage used for input/output interfaces (I/O voltages) may be higher than the core voltage to ensure compatibility with external devices and standards. I/O voltages can range from 1.8 V to 3.3 V. The power supply voltage for memory interfaces, such as those for DDR (dual data rate) RAM, can vary based on the memory standard. For example, DDR4 memory typically operates at 1.2 V, while LPDDR4 (low-power DDR) can operate around 1.1 V.

In some embodiments, after identification of a culprit path based on real-time sensor-based violation information and transition delay ATPG test result information, the identified culprit path can be subjected to small defect delay (SDD) ATPG testing. With a culprit path identified, small defect delay ATPG test patterns can be generated to test the culprit path. Generating small defect delay ATPG test patterns for a single path is much more feasible than having to generate SSD ATPG test patterns for the multitude of paths in an integrated circuit component. Small defect delay ATPG testing is then performed using these test patterns. This additional SSD ATPG testing may confirm whether the identified culprit path is the root cause of an integrated circuit component failure.

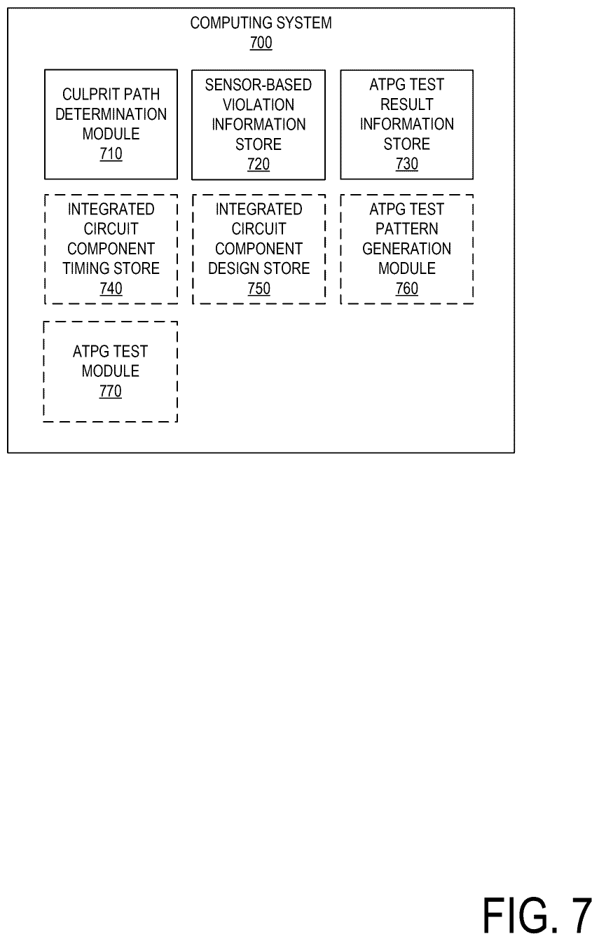

FIG. 7 is a block diagram of an example computing system 700 for identifying a culprit path in a failing integrated circuit component. The computing system 700 comprises a culprit path determination module 710, a sensor-based violation information store 720, and an ATPG test result information store 730. The culprit path determination module 710 identifies a culprit path (or more than one culprit path) that may be the root cause for an integrated circuit component experiencing failures in the field based on sensor-based violation information and transition delay ATPG test result information. The sensor-based violation information used by the culprit determination module 710 is stored in sensor-based violation information store 720 and the ATPG test result information used by the determination module 710 are stored in ATPG test result information store 730.

The computing system 700 can optionally comprise one or more of an integrated circuit component timing store 740, an integrated circuit component design store 750, an ATPG test pattern generation module 760, and an ATPG test module 770. The integrated circuit component timing store 740 can store information indicating slack information for paths in an integrated circuit component. The integrated circuit component design store 750 can store information indicating sensor-to-path associations (which sensors are associated with which paths) for an integrated circuit component. In some embodiments, the integrated circuit component design store 750 can further comprise physical design (e.g., layout information) information for an integrated circuit component. In some embodiments, any of the stores 720, 730, 740, and 750 can comprise a database (e.g., a timing database, an integrated circuit component design database). The ATPG test pattern generation module 760 can generate ATPG test patterns, such as transition delay or small delay defect ATPG test patterns. The ATPG test pattern generation module 760 can be used to generate transition delay ATPG test patterns for culprit paths identified by the determination module 710. The ATPG test module 770 can perform transition delay and small defect delay ATPG tests in an integrated circuit component using ATPG test patterns generated by the ATPG test pattern generation module 760.

It is to be understood that FIG. 7 illustrates one example of a set of modules and stores that can be included in a computing system. In other embodiments, a computing system can have more or fewer modules or stores than those shown in FIG. 7. Further, separate modules or stores can be combined into a single module or stores, and a single module or store can be split into multiple stores or modules. Moreover, any of the modules shown in FIG. 7 can be one or more software applications that can execute on a computing system. The modules shown in FIG. 7 can be implemented in software, hardware, firmware, or combinations thereof.

An integrated circuit component comprising the technologies disclosed herein to monitor and store real-time sensor-based violations during field operation of the integrated circuit component can be attached to a printed circuit board. In some embodiments, one or more additional integrated circuit components (such as a memory) or other components (such as a battery or antenna) can be attached to the printed circuit board. In some embodiments, the printed circuit board and the integrated circuit component can be located in a computing device or system that comprises a housing that encloses the printed circuit board and the integrated circuit component.

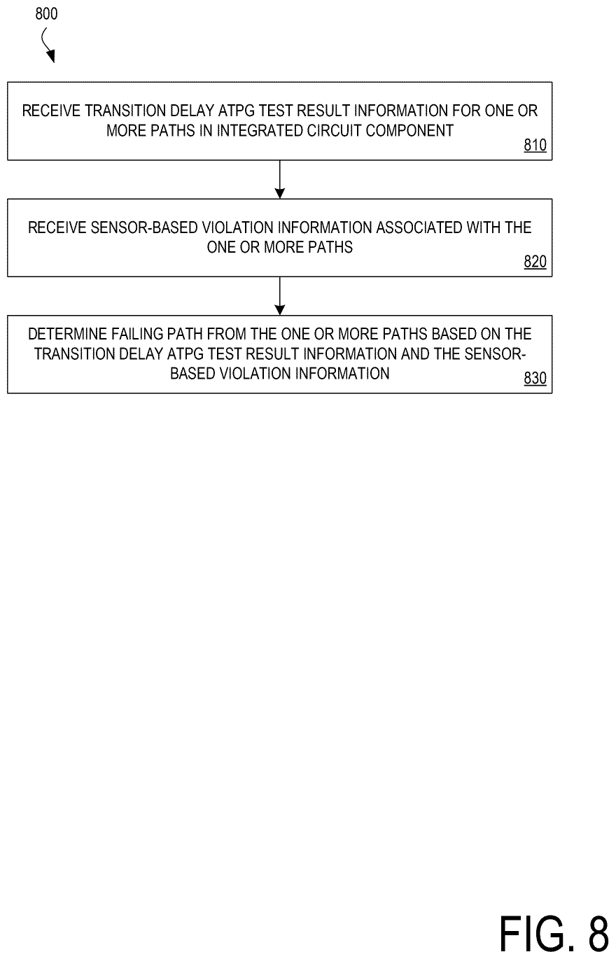

FIG. 8 is an example method of storing real-time sensor-based violations at an integrated circuit component during field operation of the integrated circuit component. The method 800 can be performed by, for example, an SoC located in a laptop computer. At 810, transition delay automatic test pattern generation (ATPG) test result information is received for one or more paths in an integrated circuit component. At 820, sensor-based violation information associated with the one or more paths is received, the sensor-based violation information indicating sensor-based violations occurring during field operation of the integrated circuit component, the sensor-based violations associated with a sensor type. At 830, a failing path is determined from among the one or more paths based on the transition delay ATPG test result information and the sensor-based violation information.

In other embodiments, the method 800 can comprise one or more additional elements. For example, the method 800 can further comprise performing ATPG testing of the integrated circuit component. In another example, the method 800 can further comprise performing transition delay ATPG testing on the failing path; and confirming that the failing path is failing based on the transition delay ATPG testing.

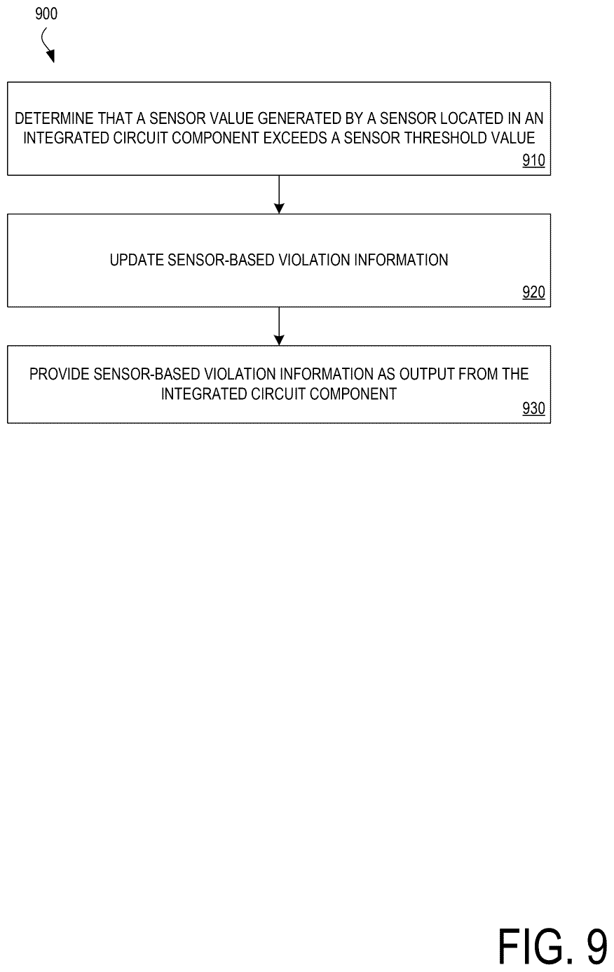

FIG. 9 is an example method of diagnosing a failing integrated circuit component to determine a culprit path in the integrated circuit component. The method 900 can be performed by, for example, an integrated circuit component manufacturer. At 910, a sensor value generated by a sensor located in an integrated circuit component is determined to exceed a sensor threshold value. At 920, in a memory located in the integrated circuit component, sensor-based violation information is updated, the sensor-based violation information indicating that the sensor threshold value has been exceeded by the sensor value. At 930, the sensor-based violation information is provided as output from the integrated circuit component, the sensor-based violation information comprising information indicating a number of times the sensor threshold value has been exceeded by the sensor value during a period of operation of the integrated circuit component.

In other embodiments, the method 900 can comprise one or more additional elements. For example, the method 900 can further comprise reading the sensor value. In another example, the method 900 can further comprises receiving a request at the integrated circuit component to provide the sensor-based violation information, wherein providing the sensor-based violation information is provided by the integrated circuit component in response to the request.

The technologies described herein can be performed by or implemented in any of a variety of computing systems, including mobile computing systems (e.g., smartphones, handheld computers, tablet computers, laptop computers, portable gaming consoles, 2-in-1 convertible computers, portable all-in-one computers), non-mobile computing systems (e.g., desktop computers, servers, workstations, stationary gaming consoles, set-top boxes, smart televisions, rack-level computing solutions (e.g., blade, tray, or sled computing systems)), and embedded computing systems (e.g., computing systems that are part of a vehicle, smart home appliance, consumer electronics product or equipment, manufacturing equipment). As used herein, the term “computing system” includes computing devices and includes systems comprising multiple discrete physical components.

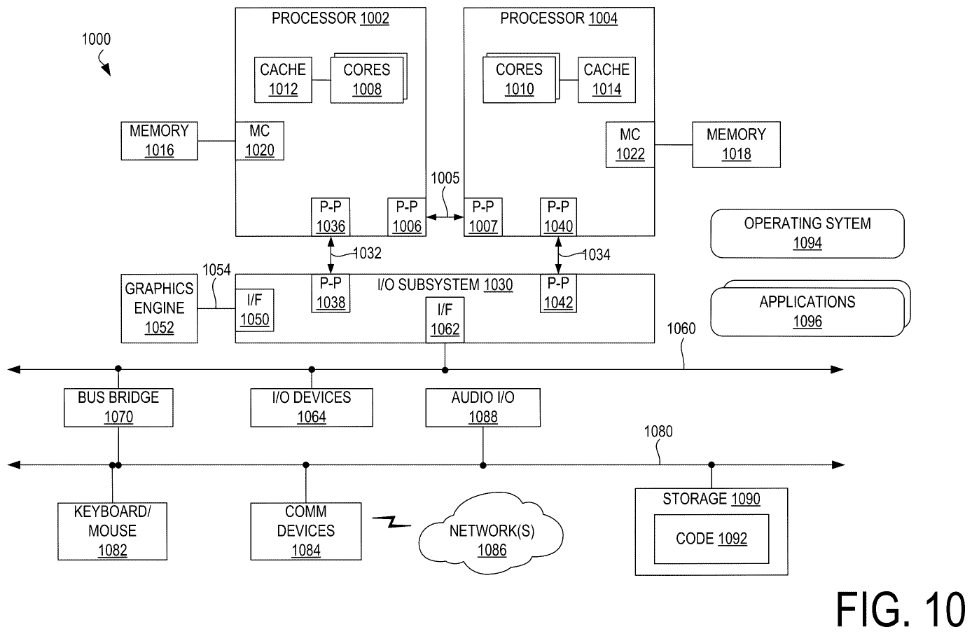

FIG. 10 is a block diagram of an example computing system in which technologies described herein (recording of real-time sensor-based violations of an integrated circuit component and diagnosis of a failing integrated circuit component) may be implemented. Generally, components shown in FIG. 10 can communicate with other shown components, although not all connections are shown, for ease of illustration. The computing system 1000 is a multiprocessor system comprising a first processor unit 1002 and a second processor unit 1004 comprising point-to-point (P-P) interconnects. A point-to-point (P-P) interface 1006 of the processor unit 1002 is coupled to a point-to-point interface 1007 of the processor unit 1004 via a point-to-point interconnection 1005. It is to be understood that any or all of the point-to-point interconnects illustrated in FIG. 10 can be alternatively implemented as a multi-drop bus, and that any or all buses illustrated in FIG. 10 could be replaced by point-to-point interconnects.

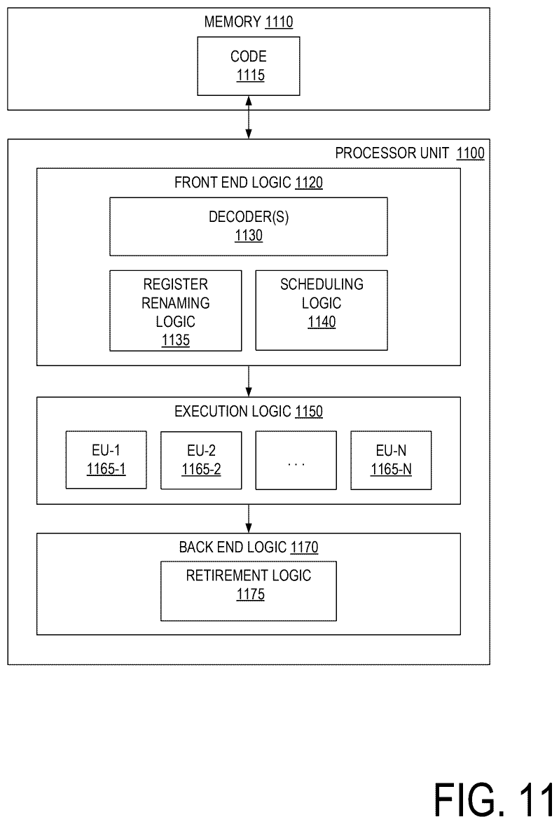

The processor units 1002 and 1004 comprise multiple processor cores. Processor unit 1002 comprises processor cores 1008 and processor unit 1004 comprises processor cores 1010. Processor cores 1008 and 1010 can execute computer-executable instructions in a manner similar to that discussed below in connection with FIG. 11, or other manners.

Processor units 1002 and 1004 further comprise cache memories 1012 and 1014, respectively. The cache memories 1012 and 1014 can store data (e.g., instructions) utilized by one or more components of the processor units 1002 and 1004, such as the processor cores 1008 and 1010. The cache memories 1012 and 1014 can be part of a memory hierarchy for the computing system 1000. For example, the cache memories 1012 can locally store data that is also stored in a memory 1016 to allow for faster access to the data by the processor unit 1002. In some embodiments, the cache memories 1012 and 1014 can comprise multiple cache levels, such as level 1 (L1), level 2 (L2), level 3 (L3), level 4 (L4) and/or other caches or cache levels. In some embodiments, one or more levels of cache memory (e.g., L2, L3, L4) can be shared among multiple cores in a processor unit or among multiple processor units in an integrated circuit component. In some embodiments, the last level of cache memory on an integrated circuit component can be referred to as a last level cache (LLC). One or more of the higher levels of cache levels (the smaller and faster caches) in the memory hierarchy can be located on the same integrated circuit die as a processor core and one or more of the lower cache levels (the larger and slower caches) can be located on an integrated circuit dies that are physically separate from the processor core integrated circuit dies.

Although the computing system 1000 is shown with two processor units, the computing system 1000 can comprise any number of processor units. Further, a processor unit can comprise any number of processor cores. A processor unit can take various forms such as a central processing unit (CPU), a graphics processing unit (GPU), general-purpose GPU (GPGPU), accelerated processing unit (APU), field-programmable gate array (FPGA), neural network processing unit (NPU), data processor unit (DPU), accelerator (e.g., graphics accelerator, digital signal processor (DSP), compression accelerator, artificial intelligence (AI) accelerator), controller, or other types of processing units. As such, the processor unit can be referred to as an XPU (or xPU). Further, a processor unit can be a system-on-a-chip (SoC) and comprise one or more of these various types of processing units. In some embodiments, the computing system comprises one processor unit with multiple cores, and in other embodiments, the computing system comprises a single processor unit with a single core. As used herein, the terms “processor unit” and “processing unit” can refer to any processor, processor core, component, module, engine, circuitry, or any other processing element described or referenced herein.

In some embodiments, the computing system 1000 can comprise one or more processor units that are heterogeneous or asymmetric to another processor unit in the computing system. There can be a variety of differences between the processing units in a system in terms of a spectrum of metrics of merit including architectural, microarchitectural, thermal, power consumption characteristics, and the like. These differences can effectively manifest themselves as asymmetry and heterogeneity among the processor units in a system.

The processor units 1002 and 1004 can be located in a single integrated circuit component (such as a multi-chip package (MCP) or multi-chip module (MCM)) or they can be located in separate integrated circuit components. An integrated circuit component comprising one or more processor units can comprise additional components, such as embedded DRAM, stacked high bandwidth memory (HBM), shared cache memories (e.g., L3, L4, LLC), input/output (I/O) controllers, or memory controllers. Any of the additional components can be located on the same integrated circuit die as a processor unit, or on one or more integrated circuit dies separate from the integrated circuit dies comprising the processor units. In some embodiments, these separate integrated circuit dies can be referred to as “chiplets”. In some embodiments where there is heterogeneity or asymmetry among processor units in a computing system, the heterogeneity or asymmetric can be among processor units located in the same integrated circuit component. In embodiments where an integrated circuit component comprises multiple integrated circuit dies, interconnections between dies can be provided by the package substrate, one or more silicon interposers, one or more silicon bridges embedded in the package substrate (such as Intel® embedded multi-die interconnect bridges (EMIBs)), or combinations thereof.

Processor units 1002 and 1004 further comprise memory controller logic (MC) 1020 and 1022. As shown in FIG. 10, MCs 1020 and 1022 control memories 1016 and 1018 coupled to the processor units 1002 and 1004, respectively. The memories 1016 and 1018 can comprise various types of volatile memory (e.g., dynamic random-access memory (DRAM), static random-access memory (SRAM)) and/or non-volatile memory (e.g., flash memory, chalcogenide-based phase-change non-volatile memories), and comprise one or more layers of the memory hierarchy of the computing system. While MCs 1020 and 1022 are illustrated as being integrated into the processor units 1002 and 1004, in alternative embodiments, the MCs can be external to a processor unit.

Processor units 1002 and 1004 are coupled to an Input/Output (I/O) subsystem 1030 via point-to-point interconnections 1032 and 1034. The point-to-point interconnection 1032 connects a point-to-point interface 1036 of the processor unit 1002 with a point-to-point interface 1038 of the I/O subsystem 1030, and the point-to-point interconnection 1034 connects a point-to-point interface 1040 of the processor unit 1004 with a point-to-point interface 1042 of the I/O subsystem 1030. Input/Output subsystem 1030 further includes an interface 1050 to couple the I/O subsystem 1030 to a graphics engine 1052. The I/O subsystem 1030 and the graphics engine 1052 are coupled via a bus 1054.

The Input/Output subsystem 1030 is further coupled to a first bus 1060 via an interface 1062. The first bus 1060 can be a Peripheral Component Interconnect Express (PCIe) bus or any other type of bus. Various I/O devices 1064 can be coupled to the first bus 1060. A bus bridge 1070 can couple the first bus 1060 to a second bus 1080. In some embodiments, the second bus 1080 can be a low pin count (LPC) bus. Various devices can be coupled to the second bus 1080 including, for example, a keyboard/mouse 1082, audio I/O devices 1088, and a storage device 1090, such as a hard disk drive, solid-state drive, or another storage device for storing computer-executable instructions (code) 1092 or data. The code 1092 can comprise computer-executable instructions for performing methods described herein. Additional components that can be coupled to the second bus 1080 include communication device(s) 1084, which can provide for communication between the computing system 1000 and one or more wired or wireless networks 1086 (e.g. Wi-Fi, cellular, or satellite networks) via one or more wired or wireless communication links (e.g., wire, cable, Ethernet connection, radio-frequency (RF) channel, infrared channel, Wi-Fi channel) using one or more communication standards (e.g., IEEE 1002.11 standard and its supplements).

In embodiments where the communication devices 1084 support wireless communication, the communication devices 1084 can comprise wireless communication components coupled to one or more antennas to support communication between the computing system 1000 and external devices.

The system 1000 can comprise removable memory such as flash memory cards (e.g., SD (Secure Digital) cards), memory sticks, Subscriber Identity Module (SIM) cards). The memory in system 1000 (including caches 1012 and 1014, memories 1016 and 1018, and storage device 1090) can store data and/or computer-executable instructions for executing an operating system 1094 and application programs 1096. The system 1000 can also have access to external memory or storage (not shown) such as external hard drives or cloud-based storage. The operating system 1094 can control the allocation and usage of the components illustrated in FIG. 10 and support the one or more application programs 1096.

The computing system 1000 can support various additional input devices, such as a touchscreen, microphone, camera, or touchpad, and one or more output devices, such as one or more speakers or displays. External input and output devices can communicate with the system 1000 via wired or wireless connections.

The system 1000 can further include at least one input/output port comprising physical connectors (e.g., USB, IEEE 1394 (FireWire), Ethernet, RS-232), a power supply (e.g., battery), and/or global satellite navigation system (GNSS) receiver (e.g., GPS receiver). The computing system 1000 can further comprise one or more additional antennas coupled to one or more additional receivers, transmitters, and/or transceivers to enable additional functions.

In addition to those already discussed, integrated circuit components, integrated circuit constituent components, and other components in the computing system 1094 can communicate with interconnect technologies such as Intel® QuickPath Interconnect (QPI), Intel® Ultra Path Interconnect (UPI), Computer Express Link (CXL), cache coherent interconnect for accelerators (CCIX®), serializer/deserializer (SERDES), Nvidia® NVLink, ARM Infinity Link, Gen-Z, or Open Coherent Accelerator Processor Interface (OpenCAPI). Other interconnect technologies may be used and a computing system 1094 may utilize more or more interconnect technologies.

It is to be understood that FIG. 10 illustrates only one example computing system architecture. Computing systems based on alternative architectures can be used to implement technologies described herein. For example, instead of the processors 1002 and 1004 and the graphics engine 1052 being located on discrete integrated circuits, a computing system can comprise an SoC (system-on-a-chip) integrated circuit incorporating multiple processors, a graphics engine, and additional components. Further, a computing system can connect its constituent component via bus or point-to-point configurations different from that shown in FIG. 10. Moreover, the illustrated components in FIG. 10 are not required or all-inclusive, as shown components can be removed and other components added in alternative embodiments.

FIG. 11 is a block diagram of an example processor unit 1100 to execute computer-executable instructions as part of implementing technologies described herein. The processor unit 1100 can be a single-threaded core or a multithreaded core in that it may include more than one hardware thread context (or “logical processor”) per processor unit.

FIG. 11 also illustrates a memory 1110 coupled to the processor unit 1100. The memory 1110 can be any memory described herein or any other memory known to those of skill in the art. The memory 1110 can store computer-executable instructions 1115 (code) executable by the processor unit 1100.

The processor unit comprises front-end logic 1120 that receives instructions from the memory 1110. An instruction can be processed by one or more decoders 1130. The decoder 1130 can generate as its output a micro-operation such as a fixed width micro-operation in a predefined format, or generate other instructions, microinstructions, or control signals, which reflect the original code instruction. The front-end logic 1120 further comprises register renaming logic 1135 and scheduling logic 1140, which generally allocate resources and queues operations corresponding to converting an instruction for execution.

The processor unit 1100 further comprises execution logic 1150, which comprises one or more execution units (EUs) 1165-1 through 1165-N. Some processor unit embodiments can include a number of execution units dedicated to specific functions or sets of functions. Other embodiments can include only one execution unit or one execution unit that can perform a particular function. The execution logic 1150 performs the operations specified by code instructions. After completion of execution of the operations specified by the code instructions, back-end logic 1170 retires instructions using retirement logic 1175. In some embodiments, the processor unit 1100 allows out of order execution but requires in-order retirement of instructions. Retirement logic 1175 can take a variety of forms as known to those of skill in the art (e.g., re-order buffers or the like).

The processor unit 1100 is transformed during execution of instructions, at least in terms of the output generated by the decoder 1130, hardware registers and tables utilized by the register renaming logic 1135, and any registers (not shown) modified by the execution logic 1150.

As used herein, the term “module” refers to logic that may be implemented in a hardware component or device, software or firmware running on a processor unit, or a combination thereof, to perform one or more operations consistent with the present disclosure. Software and firmware may be embodied as instructions and/or data stored on non-transitory computer-readable storage media. As used herein, the term “circuitry” can comprise, singly or in any combination, non-programmable (hardwired) circuitry, programmable circuitry such as processor units, state machine circuitry, and/or firmware that stores instructions executable by programmable circuitry. Modules described herein may, collectively or individually, be embodied as circuitry that forms a part of a computing system. Thus, any of the modules can be implemented as circuitry, such as culprit path determination circuitry and ATPG test circuitry. A computing system referred to as being programmed to perform a method can be programmed to perform the method via software, hardware, firmware, or combinations thereof.

Any of the disclosed methods (or a portion thereof) can be implemented as computer-executable instructions or a computer program product. Such instructions can cause a computing system or one or more processor units capable of executing computer-executable instructions to perform any of the disclosed methods. As used herein, the term “computer” refers to any computing system, device, or machine described or mentioned herein as well as any other computing system, device, or machine capable of executing instructions. Thus, the term “computer-executable instruction” refers to instructions that can be executed by any computing system, device, or machine described or mentioned herein as well as any other computing system, device, or machine capable of executing instructions.

The computer-executable instructions or computer program products as well as any data created and/or used during implementation of the disclosed technologies can be stored on one or more tangible or non-transitory computer-readable storage media, such as volatile memory (e.g., DRAM, SRAM), non-volatile memory (e.g., flash memory, chalcogenide-based phase-change non-volatile memory) optical media discs (e.g., DVDs, CDs), and magnetic storage (e.g., magnetic tape storage, hard disk drives). Computer-readable storage media can be contained in computer-readable storage devices such as solid-state drives, USB flash drives, and memory modules. Alternatively, any of the methods disclosed herein (or a portion) thereof may be performed by hardware components comprising non-programmable circuitry. In some embodiments, any of the methods herein can be performed by a combination of non-programmable hardware components and one or more processing units executing computer-executable instructions stored on computer-readable storage media.

The computer-executable instructions can be part of, for example, an operating system of the computing system, an application stored locally to the computing system, or a remote application accessible to the computing system (e.g., via a web browser). Any of the methods described herein can be performed by computer-executable instructions performed by a single computing system or by one or more networked computing systems operating in a network environment. Computer-executable instructions and updates to the computer-executable instructions can be downloaded to a computing system from a remote server.

Further, it is to be understood that implementation of the disclosed technologies is not limited to any specific computer language or program. For instance, the disclosed technologies can be implemented by software written in C++, C#, Java, Perl, Python, JavaScript, Adobe Flash, C#, assembly language, or any other programming language. Likewise, the disclosed technologies are not limited to any particular computer system or type of hardware.

Furthermore, any of the software-based embodiments (comprising, for example, computer-executable instructions for causing a computer to perform any of the disclosed methods) can be uploaded, downloaded, or remotely accessed through a suitable communication means. Such suitable communication means include, for example, the Internet, the World Wide Web, an intranet, cable (including fiber optic cable), magnetic communications, electromagnetic communications (including RF, microwave, ultrasonic, and infrared communications), electronic communications, or other such communication means.

As used in this application and the claims, a list of items joined by the term “and/of” can mean any combination of the listed items. For example, the phrase “A, B and/or C” can mean A; B; C; A and B; A and C; B and C; or A, B and C. As used in this application and the claims, a list of items joined by the term “at least one of” can mean any combination of the listed terms. For example, the phrase “at least one of A, B or C” can mean A; B; C; A and B; A and C; B and C; or A, B, and C. Moreover, as used in this application and the claims, a list of items joined by the term “one or more of” can mean any combination of the listed terms. For example, the phrase “one or more of A, B and C” can mean A; B; C; A and B; A and C; B and C; or A, B, and C.

As used in this application and the claims, the phrase “individual of” or “respective of” following by a list of items recited or stated as having a trait, feature, etc. means that all of the items in the list possess the stated or recited trait, feature, etc. For example, the phrase “individual of A, B, or C, comprise a sidewall” or “respective of A, B, or C, comprise a sidewall” means that A comprises a sidewall, B comprises sidewall, and C comprises a sidewall.

The disclosed methods, apparatuses, and systems are not to be construed as limiting in any way. Instead, the present disclosure is directed toward all novel and nonobvious features and aspects of the various disclosed embodiments, alone and in various combinations and subcombinations with one another. The disclosed methods, apparatuses, and systems are not limited to any specific aspect or feature or combination thereof, nor do the disclosed embodiments require that any one or more specific advantages be present or problems be solved.

Theories of operation, scientific principles, or other theoretical descriptions presented herein in reference to the apparatuses or methods of this disclosure have been provided for the purposes of better understanding and are not intended to be limiting in scope. The apparatuses and methods in the appended claims are not limited to those apparatuses and methods that function in the manner described by such theories of operation.

Although the operations of some of the disclosed methods are described in a particular, sequential order for convenient presentation, it is to be understood that this manner of description encompasses rearrangement, unless a particular ordering is required by specific language set forth herein. For example, operations described sequentially may in some cases be rearranged or performed concurrently. Moreover, for the sake of simplicity, the attached figures may not show the various ways in which the disclosed methods can be used in conjunction with other methods.

The following examples pertain to additional embodiments of technologies disclosed herein.

Example 1 is a method comprising: receiving transition delay automatic test pattern generation (ATPG) test result information for one or more paths in an integrated circuit component; receiving sensor-based violation information associated with the one or more paths, the sensor-based violation information indicating sensor-based violations occurring during field operation of the integrated circuit component, the sensor-based violations associated with a sensor type; and determining a failing path from among the one or more paths based on the transition delay ATPG test result information and the sensor-based violation information.

Example 2 comprises the method of example 1, further comprising performing ATPG testing of the integrated circuit component.

Example 3 comprises the method of example 1, wherein the sensor-based violation information associated with the one or more paths comprises information indicating a number of path margin monitor-based violations for one of the one or more paths.

Example 4 comprises the method of example 1, wherein the sensor-based violation information associated with the one or more paths comprises information indicating a number of temperature sensor-based violations for one of the one or more paths.

Example 5 comprises the method of example 1, wherein the sensor-based violation information associated with the one or more paths comprises information indicating a number of voltage droop monitor-based violations for one of the one or more paths.

Example 6 comprises the method of example 1, wherein the sensor-based violation information associated with the one or more paths comprises information indicating a number of aging sensor-based violations for one of the one or more paths.

Example 7 comprises the method of example 1, wherein the sensor-based violation information associated with the one or more paths comprises information indicating a number of process variation monitor-based violations.

Example 8 comprises the method of example 1, wherein the sensor type is a first sensor type, the sensor-based violations are further associated with a second sensor type and a third sensor type, wherein the first sensor type is a path margin monitor, the second sensor type is a voltage droop monitor, and the third sensor type is a temperature sensor, wherein the sensor-based violation information comprises information indicating a number of path margin monitor-based violations, a number of temperature sensor-based violations, and a number of voltage droop monitor-based violations, and wherein determining the failing path from among the one or more paths is based on the information indicating a number of sensor-based violations associated with one or more paths comprises information indicating a number of path margin monitor-based violations, a number of temperature sensor-based violations, and a number of voltage droop monitor-based violations.

Example 9 comprises the method of example 1, wherein the sensor-based violation information associated with the one or more paths comprises two or more of information indicating path margin monitor-based violations, temperature sensor-based violations, voltage droop monitor-based violations, aging sensor-based violations, and process variation monitor-based violations.

Example 10 comprises the method of example 1, wherein the one or more paths are located in a partition of the integrated circuit component, and the sensor-based violations are associated with one or more sensors located in the partition.

Example 11 comprises the method of any one of examples 1-10, wherein the sensor-based violation information associated with the one or more paths comprises information indicating a plurality of sensor-based violation counts, respective of the plurality of sensor-based violation counts associated with one of the one or more paths, and wherein determining the failing path comprises identifying a path of the one or more paths associated with a greatest sensor-based violation count among the plurality of sensor-based violation counts.

Example 12 comprises the method of any one of examples 1-10, wherein the sensor-based violation information associated with the one or more paths comprises information indicating a plurality of sensor-based violation counts, and wherein determining the failing path comprises identifying a path of the one or more paths associated with a greatest sensor-based violation count among the plurality of sensor-based violation counts and not covered by ATPG testing that generated the transition delay ATPG test result information for the one or more paths.

Example 13 comprises the method of any one of examples 1-10, wherein the sensor-based violation information associated with the one or more paths comprises information indicating a criticality of sensor-based violations associated with respective of the one or more paths, and wherein determining the failing path comprises identifying a path of the one or more paths having an associated criticality indicating that the failing path is not safe.

Example 14 comprises the method of any one of examples 1-10, wherein the sensor-based violation information associated with the one or more paths comprises information indicating a criticality of sensor-based violations associated with respective of the one or more paths, and wherein determining the failing path comprises identifying a path of the one or more paths having an associated criticality indicating that the failing path is not safe and not covered by ATPG testing that generated the transition delay ATPG test result information for the one or more paths.

Example 15 comprises the method of any one of examples 1-10, wherein the sensor type is a first sensor type, the sensor-based violations further associated with a second sensor type, wherein the sensor-based violation information associated with the one or more paths comprises information indicating a plurality of sensor-based violation counts, respective of the plurality of sensor-based violation counts associated with one of the one or more paths, and wherein determining the failing path comprises identifying as the failing path a path of the one or more paths associated with a greatest number of sensor-based violations associated with the first sensor type and a greatest number of sensor-based violations associated with the second sensor type.

Example 16 comprises the method of any one of examples 1-10, wherein the sensor type is a first sensor type, the sensor-based violations further associated with a second sensor type, wherein the sensor-based violation information associated with the one or more paths comprises information indicating a plurality of sensor-based violation counts, respective of the plurality of sensor-based violation counts associated with one of the one or more paths, and wherein determining the failing path comprises identifying as the failing path a path of the one or more paths associated with a greatest number of sensor-based violations associated with the first sensor type and a greatest number of sensor-based violations associated with the second sensor type and not covered by ATPG testing that generated the transition delay ATPG test result information for the one or more paths.

Example 17 comprises the method of any one of examples 1-10, wherein the sensor type is a first sensor type, the sensor-based violations further associated with a second sensor type, wherein the sensor-based violation information associated with the one or more paths comprises information indicating a criticality of sensor-based violations associated with respective of the one or more paths, and wherein determining the failing path comprises identifying as the failing path a path of the one or more paths having an associated criticality associated with the first sensor type indicating that the path is not safe and having an associated criticality of sensor-based violations associated with the second sensor type indicating that the path is not safe.

Example 18 comprises the method of any one of examples 1-10, wherein the sensor type is a first sensor type, the sensor-based violations further associated with a second sensor type, sensor-based violation information associated with the one or more paths comprises information indicating a criticality of sensor-based violations associated with respective of the one or more paths, and wherein determining the failing path comprises identifying as the failing path a path of the one or more paths having an associated criticality associated with the first sensor type indicating that the path is not safe and having an associated criticality of sensor-based violations associated with the second sensor type indicating that the path is not safe and not covered by ATPG testing that generated the transition delay ATPG test result information for the one or more paths.

Example 19 comprises the method of any one of examples 1-10, wherein the sensor type is a first sensor type, the sensor-based violations further associated with a second sensor type and a third sensor type, wherein the sensor-based violation information associated with the one or more paths comprises information indicating a plurality of sensor-based violation counts, respective of the plurality of sensor-based violation counts associated with one of the one or more paths, and wherein determining the failing path comprises identifying the path of the one or more paths associated with a greatest number of sensor-based violations associated with the first sensor type, a greatest number of sensor-based violations associated with the second sensor type, and a greatest number of sensor-based violations associated with the third sensor type.

Example 20 comprises the method of any one of examples 1-10, wherein the sensor type is a first sensor type, the sensor-based violations further associated with a second sensor type and a third sensor type, wherein the sensor-based violation information associated with the one or more paths comprises information indicating a plurality of sensor-based violation counts, respective of the plurality of sensor-based violation counts associated with one of the one or more paths, and wherein determining the failing path comprises identifying a path of the one or more paths associated with a greatest number of sensor-based violations associated with the first sensor type, a greatest number of sensor-based violations associated with the second sensor type, and a greatest number of sensor-based violations associated with the third sensor type and not covered by ATPG testing that generated the transition delay ATPG test result information for the one or more paths.

Example 21 comprises the method of any one of examples 1-10, wherein the sensor type is a first sensor type, the sensor-based violations further associated with a second sensor type and a third sensor type, wherein the sensor-based violation information associated with the one or more paths comprises information indicating a plurality of sensor-based violation counts, respective of the plurality of sensor-based violation counts associated with one of the one or more paths, and wherein determining the failing path comprises identifying as the failing path a path of the one or more paths having an associated criticality associated with the first sensor type indicating that the path is not safe, having an associated criticality of sensor-based violations associated with the second sensor type indicating that the path is not safe, and having an associated criticality of sensor-based violations associated with the third sensor type indicating that the path is not safe.

Example 22 comprises the method of any one of examples 1-10, wherein the sensor type is a first sensor type, the sensor-based violations further associated with a second sensor type and a third sensor type, wherein the sensor-based violation information associated with the one or more paths comprises information indicating a plurality of sensor-based violation counts, respective of the plurality of sensor-based violation counts associated with one of the one or more paths, and wherein determining the failing path comprises identifying as the failing path a path of the one or more paths having an associated criticality associated with the first sensor type indicating that the path is not safe, having an associated criticality of sensor-based violations associated with the second sensor type indicating that the path is not safe, and having an associated criticality of sensor-based violations associated with the third sensor type indicating that the path is not safe and not covered by ATPG testing that generated the transition delay ATPG test result information for the one or more paths.

Example 23 comprises the method of any one of examples 1-22, further comprising: performing transition delay ATPG testing on the failing path; and confirming that the failing path is failing based on the transition delay ATPG testing.

Example 24 is a method comprising: determining that a sensor value generated by a sensor located in an integrated circuit component exceeds a sensor threshold value; updating, in a memory located in the integrated circuit component, sensor-based violation information, the sensor-based violation information indicating that the sensor threshold value has been exceeded by the sensor value; and providing, as output from the integrated circuit component, the sensor-based violation information, the sensor-based violation information comprising information indicating a number of times the sensor threshold value has been exceeded by the sensor value during a period of operation of the integrated circuit component.

Example 25 comprises the method of example 24, further comprising reading the sensor value.

Example 26 comprises the method of example 25, wherein the sensor is a test access point compliant sensor and wherein reading the sensor value comprises converting a command to read the sensor value to one or more test access point (TAP) commands to read the sensor value.

Example 27 comprises the method of example 24, further comprising receiving a request at the integrated circuit component to provide the sensor-based violation information at the integrated circuit component, wherein providing the sensor-based violation information is provided in response to the request.

Example 28 comprises the method of example 24, wherein updating the sensor-based violation information comprises updating a counter indicating the number of times the sensor threshold value has been exceeded by the sensor value.

Example 29 comprises the method of example 24, wherein the information indicating a number of times the sensor threshold value has been exceeded by the sensor value during a period of operation of the integrated circuit component comprises information indicating a partition in the integrated circuit component within which the sensor is located.

Example 30 comprises the method of example 24, further comprising the sensor sending a message to a sensor monitor in the integrated circuit component in response to the sensor determining that the sensor value exceeds the sensor threshold value, wherein updating the sensor-based violation information is performed by the sensor monitor.

Example 31 comprises the method of example 24, wherein the sensor value exceeding the sensor threshold value is a present sensor-based violation, the method further comprises a machine learning model generating additional sensor-based violation information associated with the sensor based on the present sensor-based violation and one or more prior sensor-based violations.

Example 32 comprises the method of example 24, wherein updating the sensor-based violation information comprises updating a counter indicating a number of messages sent to a sensor monitor in the integrated circuit component in response to the sensor determining that the sensor value generated by the sensor exceeds the sensor threshold value.

Example 33 comprises the method of example 24, wherein the sensor threshold value is a borderline sensor threshold value and updating sensor-based violation information comprises updating information indicating a number of times the borderline sensor threshold value has been exceed by the sensor.

Example 34 comprises the method of example 24, wherein the sensor threshold value is a not safe sensor threshold value and updating sensor-based violation information comprises updating information indicating a number of times the not safe sensor threshold value has been exceed by the sensor.

Example 35 comprises the method of any one of examples 24-34, wherein the sensor is a path margin monitor, a temperature sensor, or a voltage droop monitor.

Example 36 comprises the method of any one of examples 24-34, wherein the sensor is an aging sensor, a process variation sensor, a clock skew monitor, or a noise sensor.

Example 37 is an apparatus, comprising: one or more processing units; and one or more non-transitory computer-readable storage media storing instructions that, when executed, cause the one or more processing units to perform the method of any one of examples 1-23.

Example 38 is an apparatus, comprising one or more non-transitory computer-readable storing media storing instructions that, when executed, cause the integrated circuit component of any one of examples 24-36 to perform the method of the any one of examples 24-36.

Example 39 is one or more non-transitory computer-readable storage media storing instructions that, when executed, cause one or more processing units to perform the method of any one of examples 1-23.

Example 40 is one or more non-transitory computer-readable storing media storing instructions that, when executed, cause the integrated circuit component of any one of examples 24-36 to perform the method of the any one of examples 24-36.

1. A method comprising:
receiving transition delay automatic test pattern generation (ATPG) test result information for one or more paths in an integrated circuit component;
receiving sensor-based violation information associated with the one or more paths, the sensor-based violation information indicating sensor-based violations occurring during field operation of the integrated circuit component, the sensor-based violations associated with a sensor type; and
determining a failing path from among the one or more paths based on the transition delay ATPG test result information and the sensor-based violation information.

2. The method of claim 1, wherein the sensor-based violation information associated with the one or more paths comprises information indicating a number of path margin monitor-based violations for one of the one or more paths.

3. The method of claim 1, wherein the sensor-based violation information associated with the one or more paths comprises information indicating a number of temperature sensor-based violations for one of the one or more paths.

4. The method of claim 1, wherein the sensor-based violation information associated with the one or more paths comprises information indicating a number of voltage droop monitor-based violations for one of the one or more paths.

5. The method of claim 1, wherein the sensor type is a first sensor type, the sensor-based violations are further associated with a second sensor type and a third sensor type, wherein the first sensor type is a path margin monitor, the second sensor type is a voltage droop monitor, and the third sensor type is a temperature sensor, wherein the sensor-based violation information comprises information indicating a number of path margin monitor-based violations, a number of temperature sensor-based violations, and a number of voltage droop monitor-based violations, and wherein determining the failing path from among the one or more paths is based on the information indicating a number of sensor-based violations associated with one or more paths comprises information indicating a number of path margin monitor-based violations, a number of temperature sensor-based violations, and a number of voltage droop monitor-based violations.

6. The method of claim 1, wherein the one or more paths are located in a partition of the integrated circuit component, and the sensor-based violations are associated with one or more sensors located in the partition.

7. The method of claim 1, wherein the sensor-based violation information associated with the one or more paths comprises information indicating a plurality of sensor-based violation counts, respective of the plurality of sensor-based violation counts associated with one of the one or more paths, and wherein determining the failing path comprises identifying a path of the one or more paths associated with a greatest sensor-based violation count among the plurality of sensor-based violation counts.

8. The method of claim 1, wherein the sensor-based violation information associated with the one or more paths comprises information indicating a plurality of sensor-based violation counts, and wherein determining the failing path comprises identifying a path of the one or more paths associated with a greatest sensor-based violation count among the plurality of sensor-based violation counts and not covered by ATPG testing that generated the transition delay ATPG test result information for the one or more paths.

9. The method of claim 1, wherein the sensor-based violation information associated with the one or more paths comprises information indicating a criticality of sensor-based violations associated with respective of the one or more paths, and wherein determining the failing path comprises identifying a path of the one or more paths having an associated criticality indicating that the failing path is not safe.

10. A method comprising:
determining that a sensor value generated by a sensor located in an integrated circuit component exceeds a sensor threshold value;
updating, in a memory located in the integrated circuit component, sensor-based violation information, the sensor-based violation information indicating that the sensor threshold value has been exceeded by the sensor value; and
providing, as output from the integrated circuit component, the sensor-based violation information, the sensor-based violation information comprising information indicating a number of times the sensor threshold value has been exceeded by the sensor value during a period of operation of the integrated circuit component.

11. The method of claim 10, further comprising receiving a request at the integrated circuit component to provide the sensor-based violation information at the integrated circuit component, wherein providing the sensor-based violation information is provided in response to the request.

12. The method of claim 10, wherein updating the sensor-based violation information comprises updating a counter indicating the number of times the sensor threshold value has been exceeded by the sensor value.

13. The method of claim 10, wherein the information indicating a number of times the sensor threshold value has been exceeded by the sensor value during a period of operation of the integrated circuit component comprises information indicating a partition in the integrated circuit component within which the sensor is located.

14. The method of claim 10, further comprising the sensor sending a message to a sensor monitor in the integrated circuit component in response to the sensor determining that the sensor value exceeds the sensor threshold value, wherein updating the sensor-based violation information is performed by the sensor monitor.

15. The method of claim 10, wherein updating the sensor-based violation information comprises updating a counter indicating a number of messages sent to a sensor monitor in the integrated circuit component in response to the sensor determining that the sensor value generated by the sensor exceeds the sensor threshold value.

16. The method of claim 10, wherein the sensor threshold value is a not safe sensor threshold value and updating sensor-based violation information comprises updating information indicating a number of times the not safe sensor threshold value has been exceed by the sensor.

17. One or more non-transitory computer-readable storage media storing instructions that, when executed, cause one or more processing units to:
receive transition delay automatic test pattern generation (ATPG) test result information for one or more paths in an integrated circuit component;
receive sensor-based violation information associated with the one or more paths, the sensor-based violation information indicating sensor-based violations occurring during field operation of the integrated circuit component, the sensor-based violations associated with a sensor type; and
determine a failing path from among the one or more paths based on the transition delay ATPG test result information and the sensor-based violation information.

18. The one or more non-transitory computer-readable storage media of claim 17, wherein the sensor type is a first sensor type, the sensor-based violations are further associated with a second sensor type and a third sensor type, wherein the first sensor type is a path margin monitor, the second sensor type is a voltage droop monitor, and the third sensor type is a temperature sensor, wherein the sensor-based violation information comprises information indicating a number of path margin monitor-based violations, a number of temperature sensor-based violations, and a number of voltage droop monitor-based violations, and wherein to determine the failing path from among the one or more paths is based on the information indicating a number of sensor-based violations associated with one or more paths comprises information indicating a number of path margin monitor-based violations, a number of temperature sensor-based violations, and a number of voltage droop monitor-based violations.

19. The one or more non-transitory computer-readable storage media of claim 17, wherein the sensor-based violation information associated with the one or more paths comprises information indicating a plurality of sensor-based violation counts, respective of the plurality of sensor-based violation counts associated with one of the one or more paths, and wherein to determine the failing path comprises to identify a path of the one or more paths associated with a greatest sensor-based violation count among the plurality of sensor-based violation counts.

20. The one or more non-transitory computer-readable storage media of claim 17, wherein the sensor-based violation information associated with the one or more paths comprises information indicating a plurality of sensor-based violation counts, and wherein to determine the failing path comprises to identify a path of the one or more paths associated with a greatest sensor-based violation count among the plurality of sensor-based violation counts and not covered by ATPG testing that generated the transition delay ATPG test result information for the one or more paths.
